(19) United States
(12) Patent Application Publication
(10) Pub. No.: US 2025/0254996 A1
(43) Pub. Date: Aug. 7, 2025

(54) DISPLAY PANEL AND DISPLAY DEVICE

(71) Applicant: Xiamen Tianma Display Technology Co., Ltd., Xiamen (CN)

(72) Inventors: Guoxing CHEN, Xiamen (CN); Sangwon LEE, Xiamen (CN); Sungwook CHANG, Xiamen (CN); Kyoungsoo LEE, Xiamen (CN)

(73) Assignee: Xiamen Tianma Display Technology Co., Ltd., Xiamen (CN)

(21) Appl. No.: 19/187,773

(22) Filed: Apr. 23, 2025

(30) Foreign Application Priority Data
Dec. 23, 2024 (CN) 202411907839.3

(51) Int. Cl. H10D 86/40; G09G 3/32; H01L 25/16; H10D 86/60; H10H 29/32

(52) U.S. Cl. CPC H10D 86/423; G09G 3/32; H01L 25/167; H10D 86/471; H10D 86/60; H10H 29/32; G09G 2300/043; G09G 2300/0819; G09G 2300/0842; G09G 2310/0286; G09G 2310/08

(57) ABSTRACT

Provided are a display panel and a display device. The display panel includes an array substrate. The array substrate includes a substrate, and a first-type transistor and a second-type transistor. The first-type transistor includes a first active layer, the second-type transistor includes a second active layer, and the second active layer is located on a side of the first active layer facing away from the substrate. Each of the first active layer and the second active layer is an oxide semiconductor active layer. By means of the technical method provided in the embodiments of the present disclosure, positions of the first active layer and the second active layer are adjusted, and further a position relationship between the first-type transistor and the second-type transistor in the array substrate is adjusted.

### CROSS-REFERENCE TO RELATED APPLICATION

This application claims priority to Chinese Patent Application No. 202411907839.3, filed on Dec. 23, 2024, the disclosure of which is incorporated herein by reference in its entirety.

TECHNICAL FIELD

Embodiments of the present disclosure relate to the field of display technologies, and in particular, to a display panel and a display device.

### BACKGROUND

With the continuous development of display technology, a display panel has been widely used in people's production and life. In particular, for the application in a virtual reality (VR)/augmented reality (AR) scenario, a finer display image and a narrower bezel are required to improve the visual perception. However, in the related art, due to problems about a device size and so on, a display panel with a high resolution is difficult to implement, affecting the overall effect of the display panel.

### SUMMARY

The present disclosure provides a display panel and a display device. Positions of the first active layer and the second active layer are adjusted, and further a position relationship between a first-type transistor and a second-type transistor in an array substrate is adjusted, so that the overall space occupied by the transistors in the array substrate can be reduced, the resolution of the display panel can be effectively improved, and the overall display effect of the display panel can be improved.

In a first aspect, an embodiment of the present disclosure provides a display panel. The display panel includes an array substrate. The array substrate includes a substrate, and a first-type transistor and a second-type transistor. The first-type transistor includes a first active layer, the second-type transistor includes a second active layer, and the second active layer is located on a side of the first active layer facing away from the substrate. Each of The first active layer and the second active layer is an oxide semiconductor active layer.

In a second aspect, an embodiment of the present disclosure provides a display device. The display device includes the display panel described in any one of the first aspect.

It is to be understood that the contents described in this section are not intended to identify key or critical features of the embodiments of the present disclosure, nor intended to limit the scope of the present disclosure. Other features of the present disclosure will be readily understood from the following Description.

### BRIEF DESCRIPTION OF THE DRAWINGS

In order to more clearly explain the technical solutions of the exemplary embodiments of the present disclosure, the drawings used for describing the embodiments will be briefly introduced below. Apparently, the drawings to be introduced are merely the drawings of part of the embodiments of the present disclosure to be described, rather than all embodiments of the present disclosure. For those skilled in the art, other drawings may also be obtained without creative work according to these drawings.

FIG. 1 is a schematic structural diagram of a display panel according to an embodiment of the present disclosure;

FIG. 2 is a schematic diagram showing a partial structure of a first-type array substrate according to an embodiment of the present disclosure;

FIG. 3 is a schematic sectional diagram taken along a section line A-A′ of FIG. 2;

FIG. 4 is a schematic sectional diagram taken along a section line B-B′ of FIG. 2;

FIG. 5 is a schematic diagram showing a partial structure of a second-type array substrate according to an embodiment of the present disclosure;

FIG. 6 is a schematic sectional diagram taken along a section line C-C′ of FIG. 5;

FIG. 7 is a schematic diagram showing a partial structure of a third-type array substrate according to an embodiment of the present disclosure;

FIG. 8 is a schematic sectional diagram taken along a section line D-D′ of FIG. 7;

FIG. 9 is a schematic structural diagram of a first type of the first-type transistor and a first type of the second-type transistor according to an embodiment of the present disclosure;

FIG. 10 is a schematic structural diagram of a second type of the first-type transistor and a second type of the second-type transistor according to an embodiment of the present disclosure;

FIG. 11 is a schematic structural diagram of a third type of the first-type transistor and a third type of the second-type transistor according to an embodiment of the present disclosure;

FIG. 12 is a schematic sectional diagram taken along a section line E-E′ of FIG. 7;

FIG. 13 is a schematic structural diagram of a pixel driving circuit according to an embodiment of the present disclosure;

FIG. 14 shows a timing of signals provided to a pixel driving circuit shown in FIG. 13 during one drive cycle according to an embodiment of the present disclosure;

FIG. 15 is a schematic diagram of a film layer of a pixel driving circuit according to an embodiment of the present disclosure;

FIG. 16 is a schematic diagram of a film layer of a first portion of FIG. 15;

FIG. 17 is a schematic diagram of a film layer of a second portion of FIG. 15;

FIG. 18 is a schematic diagram of a film layer of a third portion of FIG. 15;

FIG. 19 is a schematic diagram of a film layer of a fourth portion of FIG. 15;

FIG. 20 is a schematic diagram of stacked layers of the first portion to the fourth portion of FIG. 15;

FIG. 21 is a schematic diagram of a film layer of a fifth portion of FIG. 15;

FIG. 22 is a schematic diagram of a film layer of a sixth portion of FIG. 15;

FIG. 23 is a schematic diagram of a film layer of a seventh portion of FIG. 15;

FIG. 24 is a schematic diagram of a film layer of an eighth portion of FIG. 15;

FIG. 25 is a schematic diagram of stacked layers of a first portion to an eighth portion of FIG. 15;

FIG. 26 is a schematic diagram of a film layer of a ninth portion of FIG. 15;

FIG. 27 is a schematic diagram of a film layer of a tenth portion of FIG. 15;

FIG. 28 is a schematic sectional diagram taken along a section line F-F′ of FIG. 15;

FIG. 29 is a schematic diagram showing a partial structure of a shift register according to an embodiment of the present disclosure;

FIG. 30 is a schematic sectional diagram taken along a section line G-G′ of FIG. 29;

FIG. 31 is a schematic sectional diagram taken along a section line H-H′ of FIG. 29; and

FIG. 32 is a schematic structural diagram of a display device according to an embodiment of the present disclosure.

### DETAILED DESCRIPTION

The present disclosure will be further described in detail in conjunction with the drawings and embodiments below. It is to be understood that the specific embodiments described herein are merely used for explaining the present disclosure and are not intended to limit the present disclosure. Moreover, it is also to be noted that, for ease of description, only some, but not all, of the structures related to the present disclosure are shown in the drawings.

It is to be noted that the terms “first”, “second” and the like in the Description and claims of the present disclosure, and in the foregoing drawings, are used for distinguishing between similar objects and not necessarily for describing a particular order or sequential order. It is to be understood that the data so used are interchangeable as appropriate so that embodiments of the present disclosure described herein can be implemented in an order other than those illustrated or described herein. Moreover, the terms “include” and “have” as well as any variations thereof, are intended to cover a non-exclusive inclusion, for example, a system, a product, or a device that includes a series of units is not necessarily limited to those steps or units expressly listed, but may include other units not expressly listed or inherent to such product, or device.

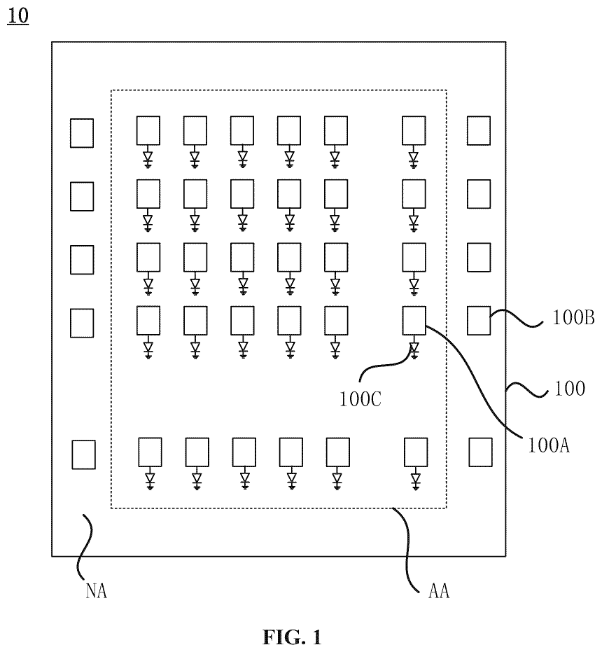

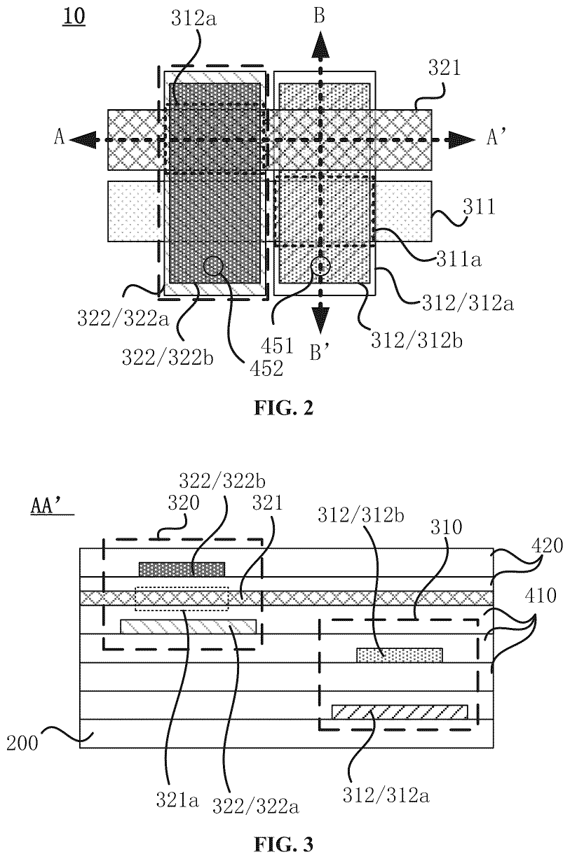

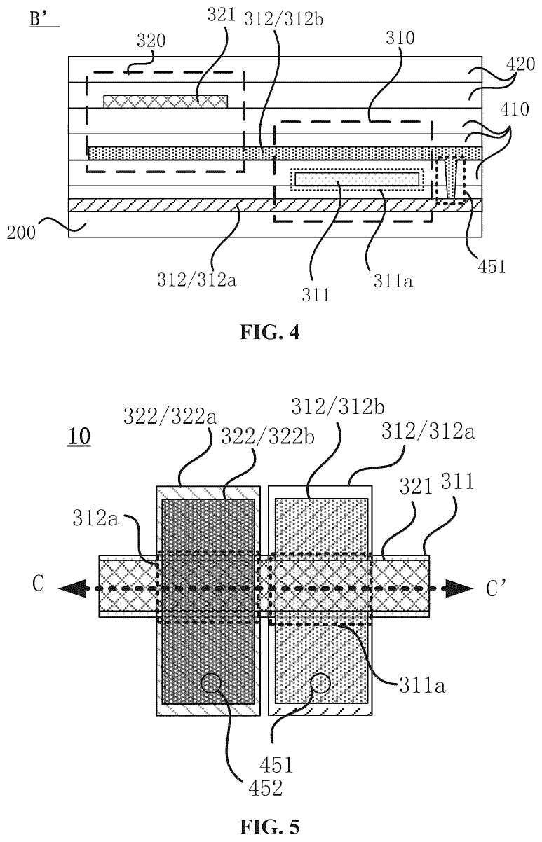

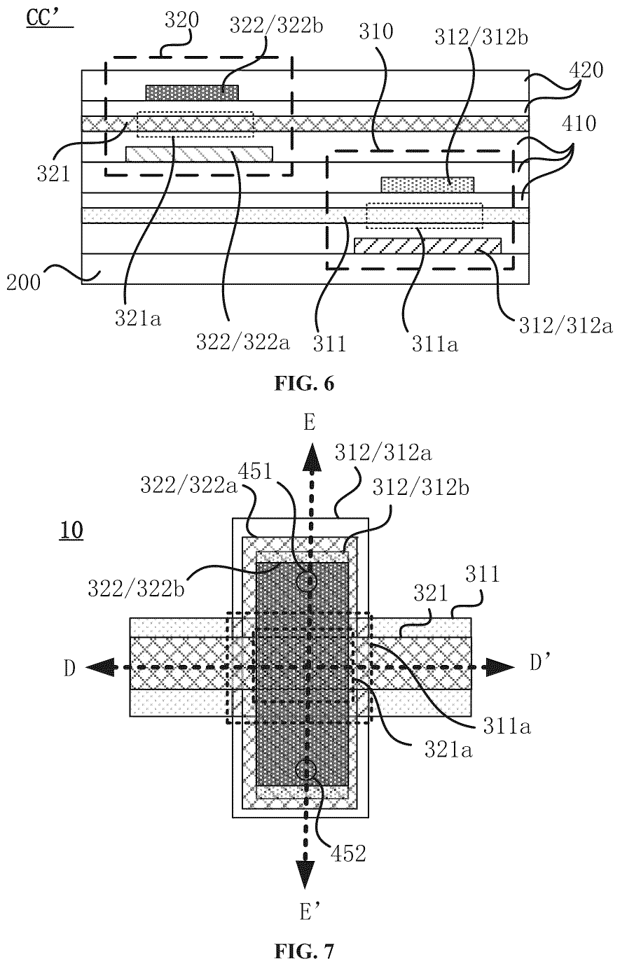

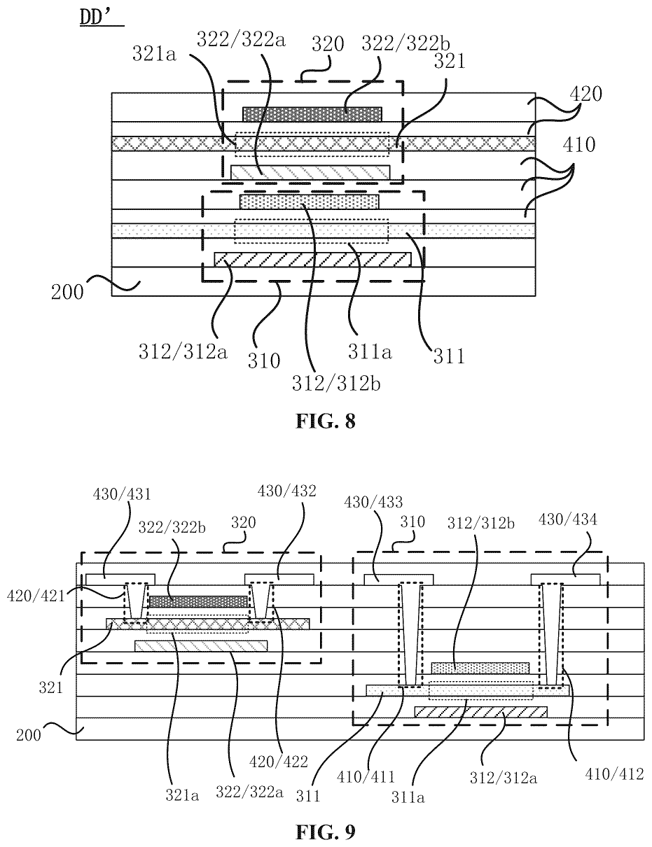

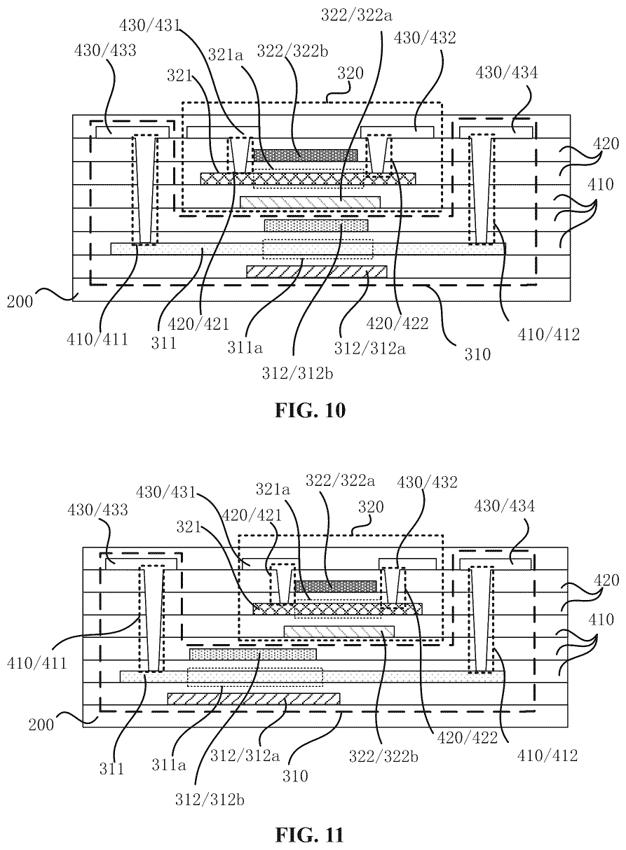

FIG. 1 is a schematic structural diagram of a display panel according to an embodiment of the present disclosure, FIG. 2 is a schematic diagram showing a partial structure of a first-type array substrate according to an embodiment of the present disclosure, FIG. 3 is a schematic sectional diagram taken along a section line A-A′ of FIG. 2, FIG. 4 is a schematic sectional diagram taken along a section line B-B′ of FIG. 2, FIG. 5 is a schematic diagram showing a partial structure of a second-type array substrate according to an embodiment of the present disclosure, FIG. 6 is a schematic sectional diagram taken along a section line C-C′ of FIG. 5, FIG. 7 is a schematic diagram showing a partial structure of a third-type array substrate according to an embodiment of the present disclosure, FIG. 8 is a schematic sectional diagram taken along a section line D-D′ of FIG. 7, FIG. 9 is a schematic structural diagram of a first type of the first-type transistor and a first type of the second-type transistor according to an embodiment of the present disclosure, and FIG. 10 is a schematic structural diagram of a second type of the first-type transistor and a second type of the second-type transistor according to an embodiment of the present disclosure. Referring to FIGS. 1 to 10, an embodiment of the present disclosure provides a display panel 10. The display panel 10 includes an array substrate 100. The array substrate 100 includes a substrate 200, a first-type transistor 310 and a second-type transistor 320. The first-type transistor 310 includes a first active layer 311, the second-type transistor 320 includes a second active layer 321, and the second active layer 321 is located on a side of the first active layer 311 facing away from the substrate 200. Each of the first active layer 311 and the second active layer 321 is an oxide semiconductor active layer.

The display panel 10 includes an array substrate 100. The array substrate 100 is provided with a pixel driving circuit 100A in a display region AA and is provided with a shift register 100B in a non-display region NA. The shift register 100B is electrically connected to the pixel driving circuit 100A for providing a scan signal. The pixel driving circuit 100A transmits a drive signal to a light-emitting element 100C under the control of a corresponding scan signal, to drive the light-emitting element 100C to emit light for display, so that the overall display effect of the display panel 10 is achieved. In the pixel driving circuit 100A or the shift register 100B, multiple transistors are provided on a side of the substrate 200. The compactness of the setting of devices in the display panel 10 can be ensured through adjusting the setting positions of the transistors in the array substrate 100, thereby more space can be saved, facilitating the miniaturization setting of the display panel 10, or more setting space can be provided for the light-emitting elements 100C, the pixel density of the display panel 10 can be increased, and the better display effect of the display panel 10 can be ensured.

In an embodiment, referring to FIGS. 1 to 10, the array substrate 100 includes a first-type transistor 310 and a second-type transistor 320. The first-type transistor 310 includes a first active layer 311, and the second-type transistor 320 includes a second active layer 321. Each of the first active layer 311 and the second active layer 321 is an oxide semiconductor active layer, that is, it may be understood that each of the first-type transistor 310 and the second-type transistor 320 is an oxide (Indium Gallium Zinc Oxide, IGZO) transistor. The oxide transistor has the advantage of low leakage current. When the transistor in the driving circuit 100A of the array substrate 100 may include the oxide transistor, the oxide transistor can reduce the influence of a leakage current on a gate potential of a drive transistor, thereby stabilizing a gate voltage of the drive transistor, improving the operation stability of the drive transistor, further ensuring the stability of the drive current, and enabling the display panel 10 according to the embodiments of the present disclosure to ensure the uniformity of the light-emitting brightness of the light-emitting element. Likewise, when the transistor in the shift register 100B in the array substrate 100 may also include the oxide transistor, the operation stability of the shift register can be ensured, and further the display effect of the whole display panel 10 can be improved.

In an embodiment, the transistor disposed in the drive circuit 100A of the array substrate 100 of the display panel 10 is the oxide transistor. By combining the advantages of the oxide transistor and utilizing the characteristic of small leakage current, a potential of a gate of the drive transistor may be maintained for a long time when the display panel 10 displays a value, so that the flicker phenomenon is improved, and the display effect of the display panel 10 is improved. In an embodiment, if the transistors in the display panel 10 are all oxide transistors, and at least part of the oxide transistors are disposed in a stacked manner, so that the space occupied by the driving circuits 100A in the display panel 10 can be saved, and thus more driving circuits 100A and light-emitting elements can be provided in the display panel 10, whereby the pixel density is increased, and the display panel 10 can display a more detailed image, that is, the visual perception of the display panel 10 by the user is enhanced. Similarly, the shift registers 100B in the display panel 10 may also all be oxide transistors. Especially when the display panel 10 performs the low-frequency driving display, the display duration of one frame of picture is relatively long; therefore, the time period during which the potential of the drive transistor needs to be held is relatively long. If a transistor connected to the gate of the drive transistor is a low-temperature polysilicon transistor, the leakage current of the low-temperature polysilicon transistor in an off state is likely to be relatively large, and the leakage current of the transistor connected to the gate of the drive transistor has a relatively large influence on the potential of the gate of the drive transistor, which may cause the significant flicker.

In an embodiment, the positions of the first-type transistor 310 and the second-type transistor 320 may be adjusted through adjusting setting positions of the first active layer 311 and the second active layer 321, thereby reducing the overall space occupied by the transistors in the array substrate 100. In an embodiment, referring to FIGS. 2 to 8, the first active layer 311 and the second active layer 321 are disposed in different layers, and the second active layer 321 is located on the side of the first active layer 311 facing away from the substrate 200. In FIGS. 2, 5 and 7, in a case where the first active layer 311 and the second active layer 321 are disposed in different layers, the first-type transistor 310 and the second-type transistor 320 may have different relative setting positions; therefore, compared with the case where two active layers are disposed in the same layer, the space occupancy ratio of the structure under the same film layer can be reduced.

Exemplarily, referring to FIGS. 2 to 4, an orthographic projection of the first active layer 311 on the substrate 200 does not overlap with an orthographic projection of the second active layer 321 on the substrate 200. Referring to FIGS. 4 to 8, the orthographic projection of the first active layer 311 on the substrate 200 may overlap with the orthographic projection of the second active layer 321 on the substrate 200, which reflects the flexibility of disposing the first active layer 311 and the second active layer 321 in different layers. As shown in FIGS. 9 and 10, when the first active layer 311 and the second active layer 321 are disposed in different layers, the first-type transistor 310 and the second-type transistor 320 have different relative setting manners. In an embodiment, the relative setting relationship of the first active layer 311 and the second active layer 321 in the display panel 10 provided in the embodiments of the present disclosure may be as shown in any one or more of the relative setting relationships in FIGS. 2, 5 and 7, which reflects that the setting manners of the first-type transistor 310 and the second-type transistor 320 are diverse. The display panel 10 may make different setting manner adjustments according to the requirements for the setting positions of the transistors in the pixel driving circuit 100A and the shift register 100B, and further, the occupation space of the transistors can be saved while ensuring the display effect of the display panel 10, which is conducive to achieving the miniaturization of the display panel 10 or providing more space for disposing the light-emitting elements 100C, increasing the pixel density of the display panel 10, and ensuring the better display effect of the display panel 10.

In conclusion, the embodiments of the present disclosure provide the display panel. The array substrate of the display panel includes the first-type transistor and the second-type transistor. The first active layer of the first-type transistor and the second active layer of the second-type transistor are disposed in different layers. Further, each of the first active layer and the second active layer is the oxide semiconductor active layer, that is, each of the first-type transistor and the second-type transistor is the oxide transistor. According to the display panel provided in the embodiments of the present disclosure, positions of the active layers in the first-type transistor and the second-type transistor are adjusted, so that the overall space occupied by the transistors in the array substrate can be reduced, and further the display panel with the higher pixel density can be achieved by saving the space, thereby improving the overall display effect of the display panel.

With continued reference to FIGS. 2 to 6 and FIG. 9, the first active layer 311 includes a first channel 311a, the second active layer 321 includes a second channel 321a, and the first channel 311a does not overlap with the second channel 321a in a direction perpendicular to a plane on which the substrate 200 is located.

The transistor includes an active layer, a gate and a source-drain. The active layer includes a channel overlapping with the gate, and a source region and a drain region doped with ions. The source is electrically connected to the source region, and the drain is electrically connected to the drain region. In an embodiment, referring to FIGS. 2 to 6, the first-type transistor 310 includes a first active layer 311 and a first gate 312 (in the direction perpendicular to the plane on which the substrate 200 is located, in FIG. 2 to FIG. 6, an example in which the first gates 312 are disposed on two sides of the first active layer 311 of the first-type transistor 310 is illustrated), and a region overlapping with the first gate 312 in the first active layer 311 is the first channel 311a, that is, in the first active layer 311, a region in which the orthographic projection of the first active layer 311 on the substrate 200 overlaps with the orthographic projection of the first gate 312 on the substrate 200 is the first channel 311a. Similarly, referring to FIGS. 2 to 6, the second-type transistor 320 includes a second active layer 321 and a second gate 322 (in the direction perpendicular to the plane on which the substrate 200 is located, in FIG. 2 to FIG. 6, an example in which the second gates 312 are disposed on two sides of the second active layer 311 of the second-type transistor 310 respectively is illustrated), and a region overlapping with the second gate 322 in the second active layer 321 is the second channel 321a, that is, in the second active layer 321, a region in which the orthographic projection of the second active layer 321 on the substrate 200 overlaps with an orthographic projection of the second gate 322 on the substrate 200 is the second channel 321a.

In an embodiment, referring to FIGS. 2 to 6, the first active layer 311 and the second active layer 321 are disposed in different layers, so that the first channel 311a located on the first active layer 311 and the second channel 321a located on the second active layer 321 are also disposed in different layers. Referring to FIG. 9, the first channel 311a and the second channel 321a are disposed in different layers, which may reflect that the first-type transistor 310 and the second-type transistor 320 are disposed in different layers. The first active layer 311 and the second active layer 321 are not disposed in the same film layer, so that more space for a film layer on which the first active layer 311 is located and a film layer on which the second active layer 321 is located can be saved, more setting space can be provided for the remaining structures and wires in the display panel 10, the overall space occupied by the transistors in the array substrate is reduced, and further the display panel with the higher pixel density can be achieved by saving the space, thereby improving the overall display effect of the display panel.

In an embodiment, referring to FIGS. 2 to 6 and FIG. 9, the first channel 311a does not overlap with the second channel 321a in the direction perpendicular to the plane on which the substrate 200 is located, it may be understood that the orthographic projection of the first channel 311a on the substrate 200 does not overlap with an orthographic projection of the second channel 321a on the substrate 200, that is, the first active layer 311 and the second active layer 321 are disposed in different layers, and the first-type transistor 310 and the second-type transistor 320 may be disposed in a staggered manner as shown in FIGS. 2 to 6 and FIG. 9, which reflects a setting manner of the first-type transistor 310 and the second-type transistor 320.

FIG. 11 is a schematic structural diagram of a third type of the first-type transistor and a third type of the second-type transistor according to an embodiment of the present disclosure. With continued reference to FIGS. 7, 8, 10 and 11, the first active layer 311 includes the first channel 311a, the second active layer 321 includes the second channel 321a, and the first channel 311a overlaps with the second channel 321a in the direction perpendicular to the plane on which the substrate 200 is located.

In an embodiment, referring to FIGS. 7 and 8, the first-type transistor 310 includes the first active layer 311 and the first gate 312, and the region overlapping with the first gate 312 in the first active layer 311 is the first channel 311a, that is, in the first active layer 311, the region where the orthographic projection of the first active layer 311 on the substrate 200 overlaps with the orthographic projection of the first gate 312 on the substrate 200 is the first channel 311a. Similarly, referring to FIGS. 7 and 8, the second-type transistor 320 includes the second active layer 321 and the second gate 322, and the region overlapping with the second gate 322 in the second active layer 321 is the second channel 321a, that is, in the second active layer 321, the region where the orthographic projection of the second active layer 321 on the substrate 200 overlaps with the orthographic projection of the second gate 322 on the substrate 200 is the second channel 321a.

In an embodiment, referring to FIGS. 7 and 8, the first active layer 311 and the second active layer 321 are disposed in different layers, so that the first channel 311a located on the first active layer 311 and the second channel 321a located on the second active layer 321 are also disposed in different layers. Referring to FIG. 10, the first channel 311a and the second channel 321a are disposed in different layers, which may reflect the first-type transistor 310 and the second-type transistor 320 are disposed in different layers. The first active layer 311 and the second active layer 321 are not disposed in the same film layer, but the first channel 311a is disposed to overlap with the second channel 321a, it may be understood that the first active layer 311 and the second active layer 321 are disposed in a laminated manner, and projections of the laminated film layer structures on the base 200 coincide, so that occupied space of the first active layer 311 on the substrate 200 coincides with occupied space of the second active layer 321 on the substrate 200, the occupied space of the first active layer 311 and the second active layer 321 in a projection direction of the substrate 200 is reduced, more setting space can be provided for the remaining structures and wires in the display panel 10, the overall space occupied by the transistors in the array substrate is reduced, and further the display panel with the higher pixel density can be achieved by saving the space, thereby improving the overall display effect of the display panel.

In an embodiment, referring to FIGS. 7, 8, 10 and 11, the first channel 311a overlaps with the second channel 321a in the direction perpendicular to the plane on which the substrate 200 is located, it may be understood that the orthographic projection of the first channel 311a on the substrate 200 overlaps with the orthographic projection of the second channel 321a on the substrate 200. FIGS. 7, 8 and 10 show that the first channel 311a and the second channel 321a substantially coincide in the direction perpendicular to the plane on which the substrate 200 is located, that is, the first channel 311a completely overlaps with the second channel 321a in the direction perpendicular to the plane on which the substrate 200 is located. In other embodiments, referring to FIG. 11, the first channel 311a may also partially overlap with the second channel 321a in the direction perpendicular to the plane on which the substrate 200 is located. It is to be noted that in the direction perpendicular to the plane on which the substrate 200 is located, the degree of overlap of the first channel 311a and the second channel 321a is also related to areas of the first channel 311a and the second channel 321a.

When the first active layer 311 and the second active layer 321 are disposed in different layers, the first channel 311a overlaps with the second channel 321a in the direction perpendicular to the plane on which the substrate 200 is located. As shown in FIG. 7, FIG. 8, FIG. 10, and FIG. 11, the first-type transistor 310 and the second-type transistor 320 may be disposed in a laminated manner, which reflects different setting manners of the first-type transistor 310 and the second-type transistor 320. The first-type transistor 310 and the second-type transistor 320 are set in a laminated manner, so that the space occupied by the multiple transistors in the array substrate 100 in a vertical direction can be better reduced, or the space occupied in a direction perpendicular to a thickness direction of the display panel 10 can be reduced, that is, the overall space occupied by the transistors in the array substrate can be better reduced, and further the display panel with the higher pixel density can be achieved by saving the space, thereby improving the overall display effect of the display panel.

With continued reference to FIGS. 2 to 4 and FIG. 9, the first-type transistor 310 includes a first gate 312, and the second-type transistor 320 includes a second gate 322. In the direction perpendicular to the plane on which the substrate 200 is located, the first gate 312 does not overlap with the second gate 322, and the first active layer 311 does not overlap with the second active layer 321.

Referring to FIGS. 2 to 4, the first-type transistor 310 includes a first active layer 311 and a first gate 312, and the second-type transistor 322 includes a second active layer 321 and a second gate 322. In the direction perpendicular to the plane on which the substrate 200 is located, the first active layer 311 does not overlap with the second active layer 321, and the first gate 312 does not overlap with the second gate 322. It may also be understood that, as shown in FIG. 2, corresponding gates and active layers of the first-type transistor 310 and the second-type transistor 320 are located in regions which are independently disposed, and no overlapping part exists, that is, the orthographic projection of the first gate 312 on the substrate 200 does not overlap with the orthographic projection of the second gate 322 on the substrate 200, and the orthographic projection of the first active layer 311 on the substrate 200 does not overlap with the orthographic projection of the second active layer 321 on the substrate 200.

In an embodiment, as shown in FIG. 2, in a case where the first active layer 311 and the second active layer 321 are disposed in different layers, the first active layer 311 and the second active layer 321 are disposed in a staggered manner, and the first gate 321 and the second gate 322 are also disposed in a staggered manner, which reflects one setting manner of the first-type transistor 310 and the second-type transistor 320. When the first-type transistor 310 and the second-type transistor 320 are provided in this setting manner, interference between a signal transmitted in the first-type transistor 310 and a signal transmitted in the second-type transistor 320 can also be avoided, thereby ensuring the stability of signal transmission in the display panel 10.

With continued reference to FIGS. 5 and 6, the first-type transistor 310 includes the first gate 312, and the second-type transistor 320 includes the second gate 322. In the direction perpendicular to the plane on which the substrate 200 is located, the first gate 312 does not overlap with the second gate 322, the first active layer 311 overlaps with the second channel 321a, and the second active layer 321 overlaps with the first channel 311a.

Referring to FIGS. 5 and 6, the first-type transistor 310 includes a first active layer 311 and a first gate 312, and the second-type transistor 322 includes a second active layer 321 and a second gate 322. In the direction perpendicular to the plane on which the substrate 200 is located, the first gate 312 does not overlap with the second gate 322. In this regard, it may also be understood that, as shown in FIG. 5, corresponding gates in the first-type transistor 310 and the second-type transistor 320 are located in regions which are independently disposed, and no overlapping part exists, that is, the orthographic projection of the first gate 312 on the substrate 200 does not overlap with the orthographic projection of the second gate 322 on the substrate 200. As for the first active layer 311 and the second active layer 321, referring to FIGS. 5 and 6, the orthographic projection of the first active layer 311 on the substrate 200 overlaps with the orthographic projection of the second channel 321a on the substrate 200, the orthographic projection of the second active layer 321 on the substrate 200 overlaps with the orthographic projection of the first channel 311a on the substrate 200, in this regard, it may be understood that the first active layer 311 includes the first channel 311a, the orthographic projection of the first active layer 311 on the substrate 200 overlaps with the orthographic projection of the second channel 321a on the substrate 200. Similarly, the second active layer 321 includes the second channel 321a, and the orthographic projection of the second active layer 321 on the substrate 200 overlaps with the orthographic projection of the first channel 311a on the substrate 200.

In other words, the first active layer 311 and the second active layer 321 are located at different film layers; however, the orthographic projection of the first active layer 311 on the substrate 200 overlaps with the orthographic projection of the second active layer 321 on the substrate 200, the first active layer 311 and the second active layer 321 are disposed in a coinciding manner, and an overlapping region of the first active layer 311 and the second active layer 321 has an overlapping region with the first gate 312 and an overlapping region with the second gate 322. In an embodiment, as shown in FIG. 5, in a case where the first active layer 311 and the second active layer 321 are disposed in different layers, the first active layer 311 and the second active layer 321 are disposed in a coinciding manner in the vertical direction of the plane on which the display panel 10 is located, but the first gate 321 and the second gate 322 are disposed in a staggered manner, which reflects another setting manner of the first-type transistor 310 and the second-type transistor 320. When the first-type transistor 310 and the second-type transistor 320 are provided in this setting manner, the space occupied by the first active layer 311 and the second active layer 321 as a whole becomes smaller, and the overall space occupied by the transistors in the array substrate can be better reduced, and further the display panel with the higher pixel density can be achieved by saving the space, thereby improving the overall display effect of the display panel.

In general, referring to FIGS. 2 to 11, the first-type transistor 310 and the second-type transistor 320 have diverse setting manners. In the array substrate 200, the pixel driving circuit or the shift register including the first-type transistor 310 and the second-type transistor 320 may adaptively adopt one or more setting manners of the above-described transistors according to an extension condition of a metal wire, a length and a cross-sectional area of the wire, to achieve the effect of saving the space as a whole.

With continued reference to FIGS. 2 to 11, the array substrate 100 further includes a first insulating layer 410, a second insulating layer 420 and a source-drain metal layer 430. The first insulating layer 410 is located between the first active layer 311 and the second active layer 321, the second insulating layer 420 is located on a side of the second active layer 321 facing away from the first active layer 311, and the source-drain metal layer 430 is located on a side of the second insulating layer 420 facing away from the second active layer 321. The source-drain metal layer includes a first source 431, a first drain 432, a second source 433 and a second drain 434. The first source 431 is connected to the second active layer 321 through a first through hole 421 disposed in the second insulating layer 420, the first drain 432 is connected to the second active layer 321 through a second through hole 422 disposed in the second insulating layer 420, the second source 433 is connected to the first active layer 311 through a third through hole 411 disposed in the second insulating layer 420 and the first insulating layer 410, and the second drain 434 is connected to the first active layer 311 through a fourth through hole 412 disposed in the second insulating layer 420 and the first insulating layer 410.

The array substrate 100 includes multiple insulating layers and metal layers which are disposed in a laminated manner. Referring to FIGS. 2 to 11, the insulating layer includes a first insulating layer 410, a second insulating layer 420 and a source-drain metal layer 430. The first insulating layer 410 is located between the first active layer 311 and the second active layer 321, and the second active layer 420 is located on a side of the second active layer 321 facing away from the first active layer 311. In conjunction with FIGS. 1 to 11, the multiple insulating layers are included between the first active layer 311 and the second active layer 321, therefore, the first insulating layer 410 may include the multiple insulating layers, for example, the first insulating layer 410 includes an interlayer insulating layer, a gate insulating layer, and the like, and the number of insulating layers in the first insulating layer 410 may be adaptively adjusted according to different display panels 10, which is not limited in the embodiments of the present disclosure.

In an embodiment, the array substrate 100 includes the source-drain metal layer 430, referring to FIGS. 9 to 11, the source-drain metal layer 430 is located on the side of the second insulating layer 420 facing away from the second active layer 321. The source-drain metal layer 430 includes a first source 431, a first drain 432, a second source 433 and a second drain 434. The first source 431 is electrically connected to the second active layer 321 of the second-type transistor 320, and the first drain 432 is electrically connected to the second active layer 321 of the second-type transistor 320, that is, the first source 431 and first drain 432 are a source-drain of the second-type transistor 320. Similarly, the second source 433 is electrically connected to the first active layer 311 of the first-type transistor 310, and the second drain 434 is electrically connected to the first active layer 311 of the first-type transistor 310, that is, the second source 433 and the second drain 434 are a source-drain of the first-type transistor 320.

In an embodiment, referring to FIGS. 9 to 11, the array substrate 100 includes a first through hole 421 and a second through hole 422. The first through hole 421 and the second through hole 422 penetrate through the second insulating layer 420. In the second-type transistor 320, the first source 431 is connected to the second active layer 321 through the first through hole 421, and the first drain 432 is connected to the second active layer through the second through hole 422 321, thereby achieving the electrical connection relationship between the first source 431, the first drain 432 and the second active layer 321. In an embodiment, referring to FIGS. 9 to 11, the array substrate 100 further includes a third through hole 411 and a fourth through hole 412. The first through hole 411 and the fourth through hole 412 penetrate through the first insulating layer 410 and the second insulating layer 420. In the first-type transistor 310, the second source 433 is connected to the first active layer 311 through the third through hole 411, and the second drain 434 is connected to the first active layer 311 through the fourth through hole 412, thereby achieving the electrical connection relationship between the second source 433, the second drain 434 and the first active layer 311.

In an embodiment, since the first source 431, the first drain 432, the second source 433 and the second drain 434 are all located on the side of the second insulating layer 420 facing away from the second active layer 321, that is, the first source 431, the first drain 432, the second source 433 and the second drain 434 are all disposed in the same layer, while the first active layer 311 and the second active layer 321 are disposed in different layers. In order to ensure that electrical connection of the first source 431 and the first drain 432 with the second active layer 321, the second source 433 and the second drain 434 are electrically connected to the first active layer 311, and each of the first insulating layer 410 and the second insulating layer 420 is designed with a through hole. The second insulating layer 420 is included between the first source 431, the first drain 432 and the second active layer 321, so that the first through hole 421 and the second through hole 422 penetrate through only the second insulating layer 420. The first insulating layer 410 and the second insulating layer 420 are included between the second source 433 and the first active layer 311 and between the second drain pole 434 and the first active layer 311, so that the third through hole 411 and the fourth through hole 412 penetrate through the first insulating layer 410 and the second insulating layer 420.

With continued reference to FIGS. 2 to 11, the first gate 312 includes a first sub-gate 312a and a second sub-gate 312b. The first sub-gate 312a is located on a side of the first active layer 311 facing the substrate 200, and the second sub-gate 312b is located on the side of the first active layer 311 facing away from the substrate 200. The second gate 322 includes a third sub-gate 322a and a fourth sub-gate 322b. The third sub-gate 322a is located on a side of the second active layer 321 facing the substrate 200, and the fourth sub-gate 322b is located on a side of the second active layer 321 facing away from the substrate 200.

In an embodiment, referring to FIGS. 2 to 11, the first gate 312 in the first-type transistor 310 may include the first sub-gate 312a and the second sub-gate 312b, and the first sub-gate 312a and the second sub-gate 312b are located on the two sides of the first active layer 311, that is, the first-type transistor 310 is of a top-bottom double-gate structure, which ensures that the first-type transistor 310 can have the better response to control signals. The first sub-gate 312a is located on the side of the first active layer 311 facing the substrate 200, and the second sub-gate 312b is located on the side of the first active layer 311 facing away from the substrate 200. Similarly, referring to FIGS. 2 to 11, the second gate 322 in the second-type transistor 320 may include the third sub-gate 322a and the fourth sub-gate 322b, and the third sub-gate 322a and the fourth sub-gate 322b are located on two sides of the second active layer 321, that is, the second-type transistor 320 is also of a top-bottom double-gate structure, which ensures that the second-type transistor 320 can have the better response to the control signals, thereby ensuring the stable transmission of the signals in the display panel 10, and ensuring the better display effect of the display panel 10.

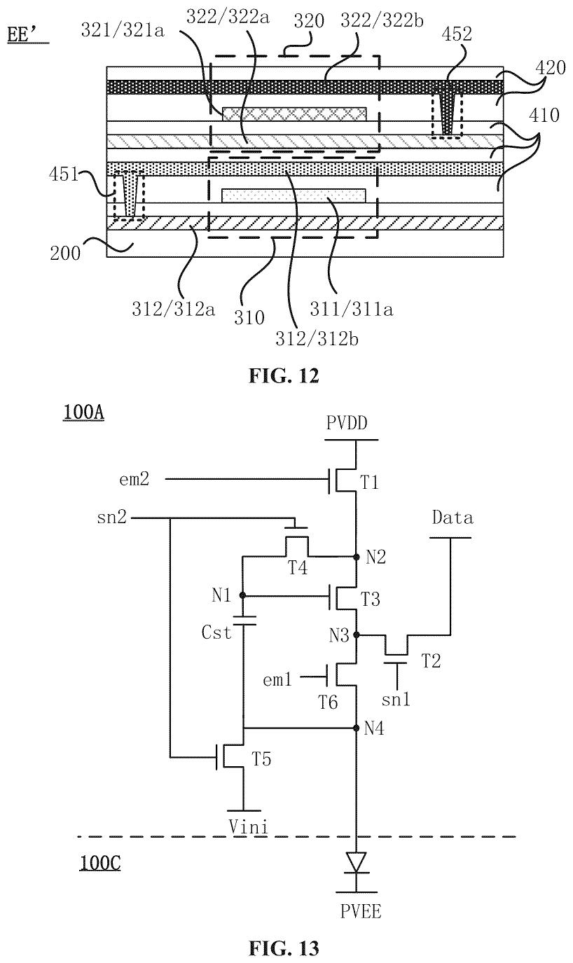

FIG. 12 is a schematic sectional diagram taken along a section line E-E′ of FIG. 7. Referring to FIGS. 1 to 12, the display panel 10 further includes an insulating layer located between the first sub-gate 312a and the first active layer 311, an insulating layer located between the first active layer 311 and the second sub-gate 312b, an insulating layer located between the third sub-gate 322a and the second active layer 321, and an insulating layer located between the second active layer 321 and the fourth sub-gate 322b. The first sub-gate 312a is connected to the second sub-gate 312b through a fifth through hole 451 of an insulating layer disposed between the first sub-gate 312a and the second sub-gate 312b, and the third sub-gate 322a is connected to the fourth sub-gate 322b through a sixth through hole 452 of an insulating layer disposed between the third sub-gate 322a and the fourth sub-gate 322b.

The first-type transistor 310 and the second-type transistor 320 are both top-bottom double-gate transistors. Referring to FIGS. 2 to 12, the insulating layer is provided between the first sub-gate 312a and the first active layer 311, the insulating layer is provided between the first active layer 311 and the second sub-gate 312b, the insulating layer is provided between the third sub-gate 322a and the second active layer 321, and the insulating layer is provided between the second active layer 321 and the fourth sub-gate 322b, to ensure the stability and the reliability of signals transmitted to each other among the first sub-gate 312a, the second sub-gate 312b, the first active layer 311, the third sub-gate 322a, the fourth sub-gate 322b, and the second active layer 321.

In an embodiment, referring to FIGS. 2 to 12, for example, FIGS. 2 and 3, the first sub-gate 312a is connected to the second sub-gate 312b through the fifth through hole 451 of the insulating layer disposed between the first sub-gate 312a and the second sub-gate 312b, and the first sub-gate 312a and the second sub-gate 312b transmit the same control signal for controlling the first-type transistor 310 to be turned on or turned off. Similarly, referring to FIGS. 2 to 12, for example, FIGS. 7 and 12, the third sub-gate 322a is connected to the fourth sub-gate 322b through the sixth through hole 452 of the insulating layer disposed between the third sub-gate 322a and the fourth sub-gate 322b, and the third sub-gate 322a and the fourth sub-gate 322b transmit the same control signal for controlling the second-type transistor 320 to be turned on or turned off.

It is to be noted that in FIGS. 2, 5 and 7, setting positions of the fifth through hole 451 and the sixth through hole 452 may be adaptively adjusted according to different display panels 10, which is not limited in the embodiments of the present disclosure.

FIG. 13 is a schematic structural diagram of a pixel driving circuit according to an embodiment of the present disclosure. With continued reference to FIGS. 1 and 13, the array substrate 100 includes a display region AA and a pixel driving circuit 100A located in the display region AA. The pixel driving circuit 100A includes a first-type transistor 310 and a second-type transistor 320.

Referring to FIG. 1, the display panel 10 includes the display region AA, and the display region AA includes the pixel driving circuit 100A and a light-emitting element 100C electrically connected to the pixel driving circuit 100A. The pixel driving circuit 100A is configured to drive the light-emitting element 100C to emit light for display, thereby achieving the display function of the display panel 10.

In an embodiment, the pixel driving circuit 100A includes multiple transistors, that is, the setting manners of the pixel driving circuit 100A are diverse. Exemplarily, referring to FIG. 13, the pixel driving circuit 100A is exemplified by the example of “6T1C”, where “T” denotes a transistor, and “C” denotes a capacitor. In different display panels 10, the pixel driving circuit 100A may be “7T1C” or “8T1C” and the like. The number of transistors in the pixel driving circuit 100A may be adaptively adjusted according to actual requirements, which is not limited in the embodiments of the present disclosure.

In a case where the pixel driving circuit 100A includes the multiple transistors, the pixel driving circuit 100A may include the first-type transistor 310 and the second-type transistor 320. The structural positions of the active layer and the gate and the like in the first-type transistor 310 and the second-type transistor 320 are adjusted, so that the overall space occupied by the pixel driving circuit 100A in the array substrate can be reduced, and further the display panel 10 with the higher pixel density can be achieved by saving the space, thereby improving the overall display effect of the display panel 10.

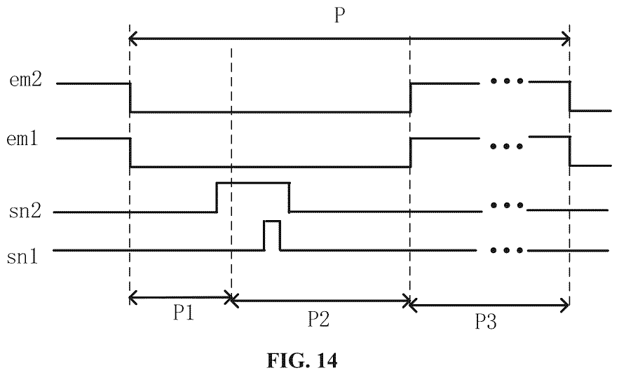

FIG. 14 shows a timing of signals provided to a pixel driving circuit shown in FIG. 13 during one drive cycle according to an embodiment of the present disclosure. With continued reference to FIGS. 1, 13 and 14, the pixel driving circuit 100A includes a drive transistor T3, a data write transistor T2, an initialization transistor T5, a threshold compensation transistor T4, a first light-emitting control transistor T1, a second light-emitting control transistor T6, and a storage capacitor Cst. A control terminal of the drive transistor T3 is electrically connected to a first node N1, a first terminal of the drive transistor T3 is electrically connected to a second node N2, and a second terminal of the drive transistor T3 is electrically connected to a third node N3. A control terminal of the first light-emitting control transistor T1 is electrically connected to a first light-emitting control signal line em2, a first terminal of the first light-emitting control transistor T1 is electrically connected to a first voltage terminal PVDD, and a second terminal of the first light-emitting control transistor T1 is electrically connected to the second node N2. A control terminal of the threshold compensation transistor T4 is electrically connected to a first scan signal line sn2, a first terminal of the threshold compensation transistor T4 is electrically connected to the second node N2, and a second terminal of the threshold compensation transistor T4 is electrically connected to the first node N1. A first terminal of the storage capacitor Cst is electrically connected to the first node N1, and a second terminal of the storage capacitor Cst is electrically connected to a fourth node N4. A control terminal of the initialization transistor T5 is electrically connected to the first scan signal line sn2, a first terminal of the initialization transistor T5 is electrically connected to the fourth node N4, and a second terminal of the initialization transistor T5 is electrically connected to the initialization voltage signal line Vini. A control terminal of the data write transistor T2 is electrically connected to a second scan signal line sn1, a first terminal of the data write transistor T2 is electrically connected to a data line Data, and a second terminal of the data write transistor T2 is electrically connected to the third node N3. A control terminal of the second light-emitting control transistor T6 is electrically connected to a second light-emitting control signal line em1, a first terminal of the second light-emitting control transistor T6 is electrically connected to the third node N3, and a second terminal of the second light-emitting control transistor T6 is electrically connected to the fourth node N4.

In an embodiment, the setting manners of the pixel driving circuit 100A are diverse, and thus the setting types of the display panel 10 are also diverse. Referring to FIGS. 13 and 14, the pixel driving circuit 100A is exemplified as “6T1C”. Referring to FIG. 13, the pixel circuit 100 may include the drive transistor T3, the data write transistor T2, the initialization transistor T5, the threshold compensation transistor T4, the first light-emitting control transistor T1, the second light-emitting control transistor T6, and the storage capacitance Cst. A type of the transistor in the pixel driving circuit 100A may be the oxide transistor.

In an embodiment, for a timing work process of the pixel driving circuit 100A, referring to FIGS. 13 and 14, the first scan signal line sn2 connected to the control terminal of the initialization transistor T5 may control turning on and off of the initialization transistor T5, and a reset signal in the initialization voltage signal line Vini connected to an input terminal of the initialization transistor T5 is written into a gate of the drive transistor T3 when the initialization transistor T5 is turned on, to reset the first node N1. The storage capacitor Cst is configured to ensure that the potential of the first node NI is stabilized. The second scan signal line sn1 connected to the control terminal of the data write transistor T2 may control turning on and off of the data write transistor T2, and a data signal on the data line Data is written into the first electrode of the drive transistor T3 when the data write transistor T2 is turned on. The first scan signal line sn2 connected to the control terminal of the threshold compensation transistor T4 may control turning on and off of the threshold compensation transistor T4, and the drive transistor T3 is compensated for the threshold voltage when the threshold compensation transistor T4 is turned on. The first light-emitting control signal line em2 connected to the control terminal of the first light-emitting control transistor T1 and the second light-emitting control signal line em1 connected to the control terminal of the second light-emitting control transistor T6 may control turning on and off of the first light-emitting control transistor T1 and the second light-emitting control transistor T6, and a power signal transmitted from the first voltage terminal PVDD is written into the light-emitting element 100C when the first light-emitting control transistor TI and the second light-emitting control transistor T6 are turned on, thereby achieving the display and light emission of the light-emitting element 100C. In an embodiment, referring to FIG. 14, one frame time of the display panel 10 includes at least an initialization write stage P1, a data write stage P2 and a light-emitting stage P3. In the initialization stage P1, the initialization transistor T5 is turned on under the control of the first scan signal line sn2, and the reset signal in the initialization voltage signal line Vini is written into the first node N1 electrically coupled to the gate of the drive transistor T3 to initialize the gate of the drive transistor T3. Moreover, since the threshold compensation transistor T4 is turned on, the reset signals in the initialization voltage signal line Vini are simultaneously written into the second terminal of the second light-emitting control transistor T6, i.e., the node N4, to reset the light-emitting element 100c. In the data write stage P2, the data write transistor T2 is turned on under the control of the second scan signal line sn1, and the threshold compensation transistor T4 is turned on under the control of the first scan signal line sn2, so that the data signal is written into the gate of the drive transistor T3 through the data write transistor T2, the drive transistor T3 and the threshold compensation transistor T4 in sequence. In the light-emitting stage P3, the first light-emitting control transistor T1 and the second light-emitting control transistor T6 are turned on under the control of the first light-emitting control signal line em2 and the second light-emitting control signal line em1, respectively, so that a drive current generated by the drive transistor T3 may be transmitted to an anode of the light-emitting element 100C to further drive the light-emitting element 100C to emit light.

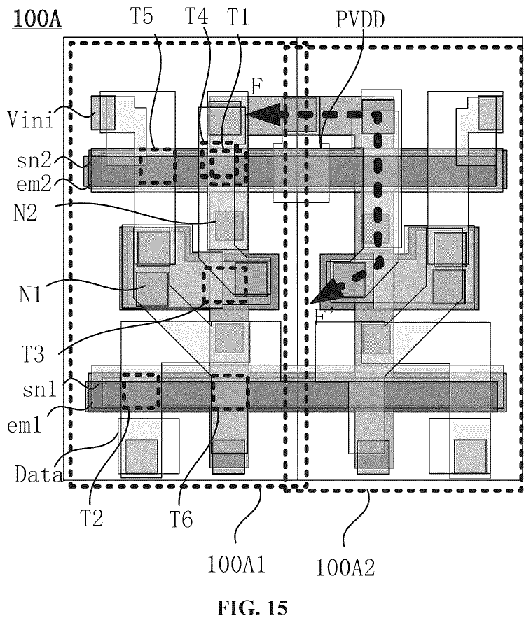

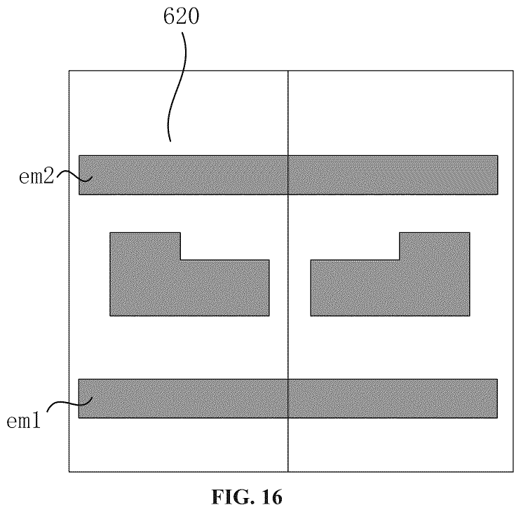

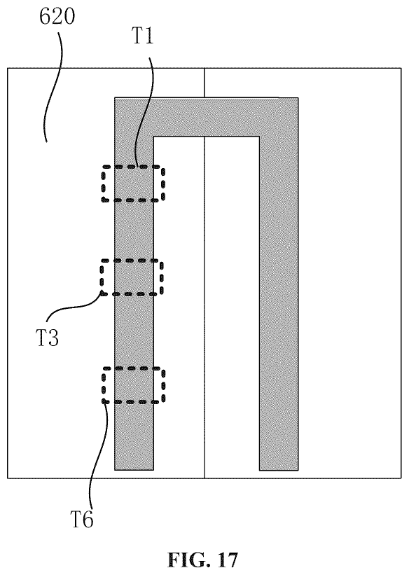

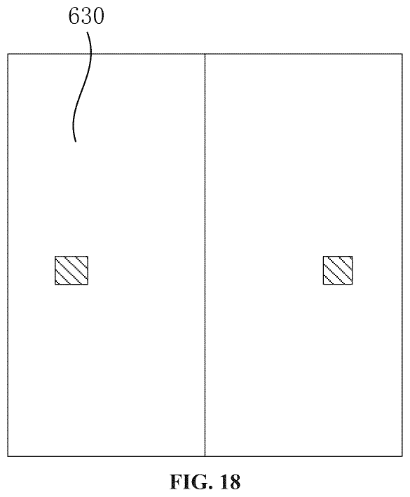

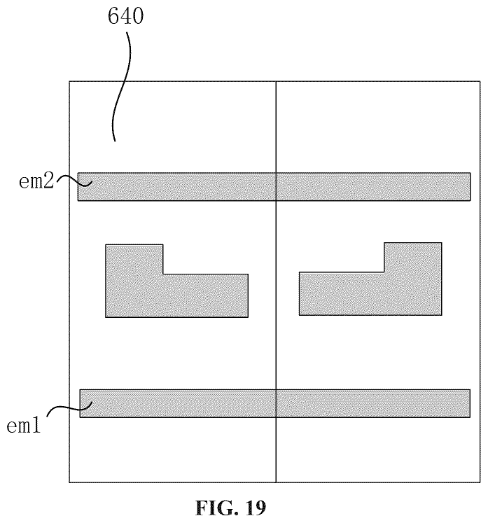

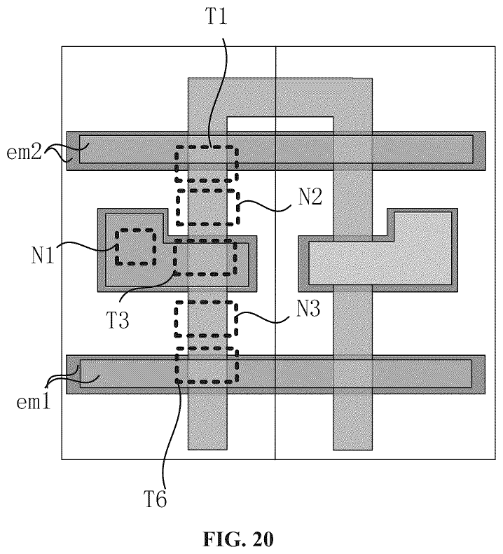

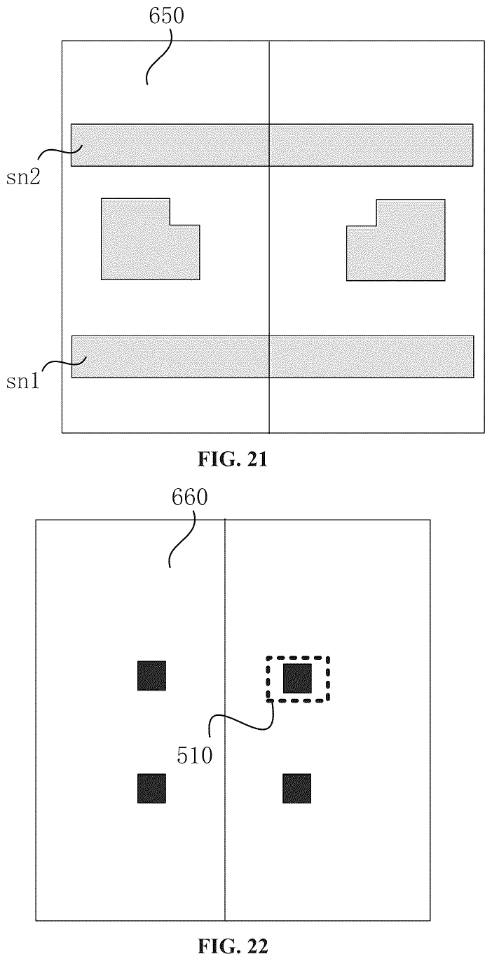

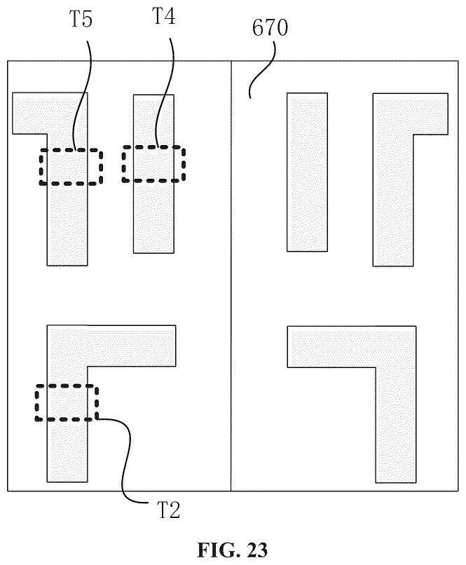

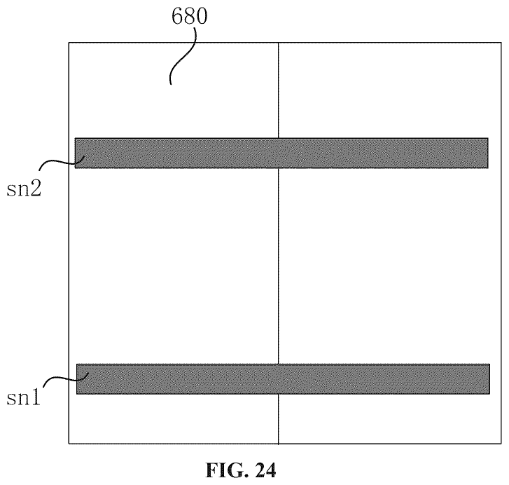

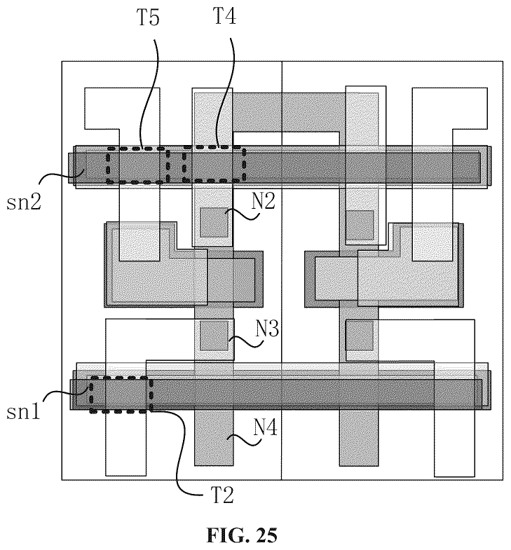

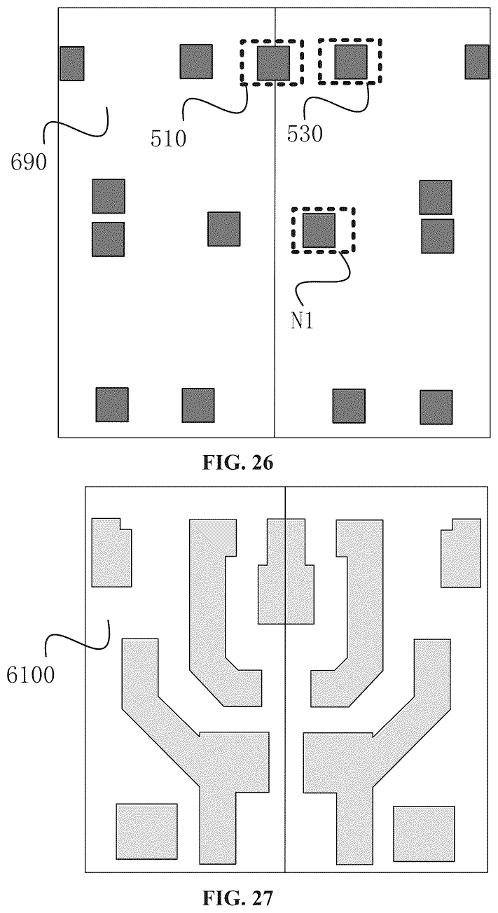

FIG. 15 is a schematic diagram of a film layer of a pixel driving circuit according to an embodiment of the present disclosure, FIG. 16 is a schematic diagram of a film layer of a first portion of FIG. 15, FIG. 17 is a schematic diagram of a film layer of a second portion of FIG. 15, FIG. 18 is a schematic diagram of a film layer of a third portion of FIG. 15, FIG. 19 is a schematic diagram of a film layer of a fourth portion of FIG. 15, FIG. 20 is a schematic diagram of stacked layers of the first portion to the fourth portion of FIG. 15, FIG. 21 is a schematic diagram of a film layer of a fifth portion of FIG. 15, FIG. 22 is a schematic diagram of a film layer of a sixth portion of FIG. 15, FIG. 23 is a schematic diagram of a film layer of a seventh portion of FIG. 15, FIG. 24 is a schematic diagram of a film layer of an eighth portion of FIG. 15, FIG. 25 is a schematic diagram of stacked layers of a first portion to an eighth portion of FIG. 15, FIG. 26 is a schematic diagram of a film layer of a ninth portion of FIG. 15, and FIG. 27 is a schematic diagram of a film layer of a tenth portion of FIG. 15. Referring to FIGS. 13 to 27, the display panel 10 is formed by multiple film layers disposed to overlap with each other. As shown in FIG. 15, the film layer structure of the pixel driving circuit 100A shown in FIG. 15 may be the pixel driving circuit 100A provided in FIG. 13. In an embodiment, referring to FIGS. 16 to 27, the film layer structure of the pixel driving circuit 100 may include relevant film layers of an insulating layer 610 to an insulating layer 6100 and a relevant film layer of the pixel driving circuit 100A located on the insulating layer, and these film layers are provided in sequence from the substrate 200 to a light emission side of the display panel 10. As shown in FIGS. 15 to 27 and in conjunction with FIGS. 2 to 12, the insulating layer 610 is an insulating layer on the side of the first active layer 311 facing the substrate 200, and the first sub-gate 312a may be disposed on the insulating layer 610; the first active layer 311 may be disposed on the side of the insulating layer 620 facing away from the substrate 200; an insulating layer 630 is disposed between the first active layer 311 and the second sub-gate 312b; the second sub-gate 312b is disposed on a side of an insulating layer 640 facing away from the substrate 200; the third sub-gate 322a is disposed on a side of the insulating layer 620 facing away from the substrate 200, an insulating layer 660 is disposed between the third sub-gate 322a and the second active layer 321, and the second active layer 321 is located on a side of an insulating layer 670 facing away from the substrate 200, the fourth sub-gate 322b is disposed on a side of an insulating layer 680 facing away from the substrate 200, and an insulating layer 690 and the insulating layer 6100 are also included on a side of the fourth sub-gate 322b facing away from the substrate 200, where the source-drain metal layer 430 is disposed on a side of the insulating layer 6100 facing away from the substrate 200. For the specific film layer structure of the pixel driving circuit 100A, it may be adaptively adjusted according to actual requirements, such as adding or subtracting part of the film layers, and any one of the above-described film layers may include at least one sub-layer, which is not limited in the embodiments of the present disclosure.

Referring to FIGS. 1 to 27, each of the drive transistor T3, the first light-emitting control transistor T1 and the second light-emitting control transistor T2 is the first-type transistor 310, and each of the data write transistor T2, the threshold compensation transistor T4 and the initialization transistor T5 is the second-type transistor.

The pixel driving circuit 100A of the display panel 10 includes the first-type transistor 310 and the second-type transistor 320, so that it is ensured that the space occupancy ratio of the pixel driving circuit 100A in the array substrate 100 is relatively small, thereby improving the overall display effect of the display panel 10.

Each of the drive transistor T3, the first light-emitting control transistor TI and the second light-emitting control transistor T2 in the pixel driving circuit 100A may be the first-type transistor 310, each of the active layers corresponding to the drive transistor T3, the first light-emitting control transistor T1 and the second light-emitting control transistor T2 is the first active layer 311, and the first active layer 311 may be disposed on the side of the insulating layer 620 facing away from the substrate 200, as shown in FIG. 17. Each of the data write transistor T2, the threshold compensation transistor T4 and the initialization transistor T5 in the pixel driving circuit 100A may be the second-type transistor, and each of the active layers corresponding to the data write transistor T2, the threshold compensation transistor T4 and the initialization transistor T5 is the second active layer 321, and the second active layer 321 may be disposed on the side of the insulating layer 670 facing away from the substrate 200. When the transistors in the pixel driving circuit 100A are all oxide transistors, active layers corresponding to different transistors in the pixel driving circuit 100A are adjusted to be disposed in different layers, so that the display stability of the display panel 10 can be ensured, the size of the pixel driving circuit 100A can be compressed, and thus more space can be saved, moreover, the pixel density can be increased, and thus the display effect of the display panel 10 can be improved.

With continued reference to FIGS. 15 to 27, the pixel driving circuit 100A includes a first pixel driving circuit 100A1 and a second pixel driving circuit 100A2, and the first pixel circuit 100A1 and the second pixel circuit 100A2 are disposed in axial symmetry.

In an embodiment, the pixel driving circuit 100A includes the first pixel driving circuit 100A1 and the second pixel driving circuit 100A2. Referring to FIGS. 15 to 27, the first pixel circuit 100A1 and the second pixel circuit 100A2 are disposed in axial symmetry, whereby a setting position of the transistor in the first pixel circuit 100A1 and a setting position of the transistor in the second pixel circuit 100A2 are also disposed in axial symmetry. The first pixel driving circuit 100A1 and the second pixel driving circuit 100A2 are provided, so that the setting space of the transistor provided by the array substrate 100 in the display panel 10 can be better utilized, and the regularity of the display panel 10 can be improved.

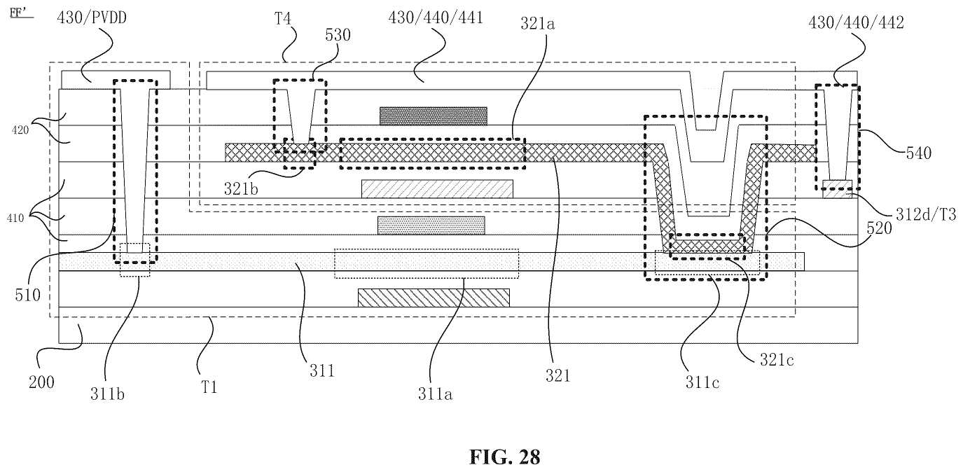

FIG. 28 is a schematic sectional diagram taken along a section line F-F′ of FIG. 15. Referring to FIGS. 1 to 28, a channel of the first light-emitting control transistor T1 overlaps with a channel of the threshold compensation transistor T4 in the direction perpendicular to the plane on which the substrate 200 is located. The array substrate 100 further includes a first insulating layer 410, a second insulating layer 420 and a source-drain metal layer 430. The first insulating layer 410 is located between the first active layer 311 and the second active layer 321, the second insulating layer 420 is located on the side of the second active layer 321 facing away from the first active layer 311, and the source-drain metal layer 430 is located on the side of the second insulating layer 420 facing away from the second active layer 321. The source-drain metal layer 430 includes a source of the first light-emitting control transistor T1 and a source alignment 440 of the threshold compensation transistor T4, the source of the first light-emitting control transistor T1 is connected to an active layer of a source region of the first light-emitting control transistor T1 through a seventh through hole 510 disposed in the second insulating layer 420 and the first insulating layer 410, an active layer of a drain region of the first light-emitting control transistor T1 is connected to an active layer of a drain region of the threshold compensation transistor T4 through an eighth through hole 520 disposed in the first insulating layer 410, a first terminal 441 (a source of the threshold compensation transistor T4) of the source wire 440 of the threshold compensation transistor T4 is connected to the second active layer 312 through a ninth through hole 530 disposed in the second insulating layer 420, and a second terminal 442 of the source wire 440 of the threshold compensation transistor T4 is connected to a gate of the drive transistor T3 through a tenth through hole 540 disposed in the second insulating layer 420 and the first insulating layer 410.

In an embodiment, referring to FIGS. 15, 17 and 28, the first light-emitting control transistor T1 is the first-type transistor 310, and an active layer (i.e., the first active layer 311 in the first-type transistor 310) corresponding to the first light-emitting control transistor T1 and a channel (i.e., the first channel 311a in the first-type transistor 310) corresponding to the active layer of the first light-emitting control transistor T1 may be shown in a film layer diagram. Referring to FIGS. 15, 23 and 28, the threshold compensation transistor T4 is the second-type transistor 320, and an active layer (i.e., the second active layer 321 in the second-type transistor 320) corresponding to the threshold compensation transistor T4 and a channel (i.e., the second channel 321a in the second-type transistor 320) corresponding to the active layer of the threshold compensation transistor T4 may be shown in the film layer diagram. Referring to FIGS. 15 and 28, the channel of the first light-emitting control transistor T1 overlaps with the channel of the threshold compensation transistor T4, that is, an overlapping region exists between an orthographic projection of the channel of the first light-emitting control transistor T1 on the substrate 200 and an orthographic projection of the channel of the threshold compensation transistor T4 on the substrate 200, and it can be understood that the first light-emitting control transistor T1 and the threshold compensation transistor T4 are disposed to overlap up and down in the thickness direction of the substrate 200.

In an embodiment, referring to FIGS. 15 to 28, the source-drain metal layer 430 is located on the side of the insulating layer 6100 facing away from the substrate 200, and the source-drain metal layer 430 includes a source wire and a drain wire of the transistor in the pixel driving circuit 100A. In an embodiment, referring to FIGS. 15 to 28, for example, FIGS. 26 and 28, the source of the first light-emitting control transistor T1 is connected to the active layer of the source region (referenced to 311b shown in FIG. 28) of the first light-emitting control transistor T1 through the seventh through hole 510, to electrically connect the first light-emitting control transistor T1 to the first voltage terminal PVDD and transmit a positive power supply signal to the pixel driving circuit 100 A through the first light-emitting control transistor T1. In an embodiment, referring to FIGS. 15 to 28, for example, FIGS. 22 and 28, the active layer in the drain region (311c shown in FIG. 28) of the first light-emitting control transistor T1 is connected to the active layer in the drain region of the threshold compensation transistor T4 (321c shown in FIG. 28) through the eighth through hole 520.

In an embodiment, referring to FIGS. 15 to 28, for example, FIGS. 26 and 28, a first terminal of the source of the threshold compensation transistor T4 is connected to the second active layer 312 through the ninth through hole 530, that is, the source of the threshold compensation transistor T4 is electrically connected, through the ninth through hole 530, to an active layer corresponding to the threshold compensation transistor T4, and for example, to the source region (321b shown in FIG. 28) of the threshold compensation transistor T4. Referring to FIGS. 15 to 28, for example, FIGS. 15 and 26, a second terminal 442 of the source of the threshold compensation transistor T4 is connected to the gate (312d shown in FIG. 28) of the drive transistor T3 through the tenth through hole 540, i.e., the through hole at the first node N1. Referring to FIG. 28, and the channel 311a of the drive transistor T3 is electrically connected to the second terminal 442 of the source of the threshold compensation transistor T4.

Positions of the active layer, the source and the drain in the first light-emitting control transistor T1 and the threshold compensation transistor T4 are described, it reflects a difference-layer setting relationship of the first light-emitting control transistor T1 and the threshold compensation transistor T4, or a relative position relationship of the first light-emitting control transistor T1 and the threshold compensation transistor T4 may be shown in FIGS. 7 and 8. In an embodiment, a relative position relationship of the first light-emitting control transistor T1 and the initialization transistor T5 may be shown in FIGS. 5 and 6. In an embodiment, a relative position relationship of the first light-emitting control transistor T1 and the second light-emitting control transistor T2 may be shown in FIGS. 2 to 4. Therefore, in the pixel driving circuit 100A, relative setting manners of the first-type transistor 310 and the second-type transistor 320 in the pixel driving circuit 100A are diverse, and in combination with different and similar setting manners, the space occupied by the pixel driving circuit 100A in the array substrate 100 can be further reduced, and further the display panel 10 with the higher pixel density can be achieved by saving the space, thereby improving the overall display effect of the display panel 10.

With continued reference to FIG. 15, FIG. 16, FIG. 19 to FIG. 21, FIG. 24, and FIG. 25, in the plane on which the substrate 200 is located, the first light-emitting control signal line em2 and the first scan signal line sn2 extend in the same direction and at least partially overlap, and the channel of the first light-emitting control transistor T1 is disposed to overlap with the channel of the threshold compensation transistor T4 in the direction perpendicular to the substrate 200.

In an embodiment, the first light-emitting control signal line em2 electrically connected to the control terminal of the first light-emitting control transistor T1 and the first scan signal line sn2 electrically connected to the control terminal of the threshold compensation transistor T4 extend in the same direction. Referring to FIG. 15, FIG. 16, FIG. 19 to FIG. 21, FIG. 24 and FIG. 25, both the first light-emitting control signal line em2 and the first scan signal line sn2 extend in a transverse direction of the drawings. In an embodiment, the first light-emitting control signal line em2 provides a control signal for the first light-emitting control transistor T1, and a region where the first light-emitting control signal line em2 overlaps with the active layer of the first light-emitting control transistor T1 is the channel of the first light-emitting control transistor T1. The first scan signal line sn2 provides a control signal for the threshold compensation transistor T4, and a region where the first scan signal line sn2 overlaps with the active layer of the threshold compensation transistor T4 is the channel of the threshold compensation transistor T4.

In an embodiment, the first light-emitting control transistor T1 is the first-type transistor 310, and the threshold compensation transistor T4 is the second-type transistor 320, and the channel of the first light-emitting control transistor T1 is disposed to overlap with the channel of the threshold compensation transistor T4 in the direction perpendicular to the substrate 200, which reflects the laminating setting manner of the first light-emitting control transistor T1 and the threshold compensation transistor T4. In an embodiment, the relative position relationship of the first light-emitting control transistor T1 and the threshold compensation transistor T4 may be shown in FIGS. 7 and 8.

With continued reference to FIG. 15, FIG. 16, FIG. 19 to FIG. 21, FIG. 24 and FIG. 25, in the plane on which the substrate 200 is located, the second light-emitting control signal line em1 and the second scan signal line sn1 extend in the same direction and at least partially overlap.

In an embodiment, the second light-emitting control signal line em1 electrically connected to the control terminal of the second light-emitting control transistor T6 and the second scan signal line sn1 electrically connected to the control terminal of the data write transistor T2 extend in the same direction and partially overlap. Referring to FIG. 15, FIG. 16, FIG. 19 to FIG. 21, FIG. 24 and FIG. 25, both the second light-emitting control signal line em1 and the second scan signal line sn1 extend in a transverse direction of the drawings. In an embodiment, the second light-emitting control signal line em1 provides a control signal for the second light-emitting control transistor T6, and a region where the second light-emitting control signal line em1 overlaps with the active layer of the second light-emitting control transistor T6 is the channel of the second light-emitting control transistor T6. The second scan signal line sn1 provides a control signal for the data write transistor T2, and a region where the second scan signal line sn1 overlaps with the active layer of the data write transistor T2 is the channel of the data write transistor T2.

In an embodiment, the second light-emitting control transistor T6 is the first-type transistor 310, and the data write transistor T2 is the second-type transistor 320. The second light-emitting control signal line em1 providing the control signal to the second light-emitting control transistor T6 and the second scan signal line sn1 providing the control signal to the data write transistor T2 extend in the same direction, but the channel of the second light-emitting control transistor T6 does not overlap with the channel of the data write transistor T2, which reflects one setting manner of the second light-emitting control transistor T2 and the data write transistor T2. In an embodiment, a relative position relationship of the second light-emitting control transistor T2 and the data write transistor T2 may be shown in FIGS. 4 and 5.

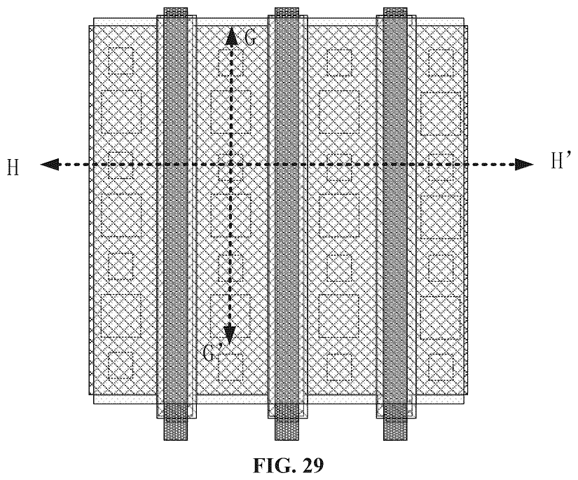

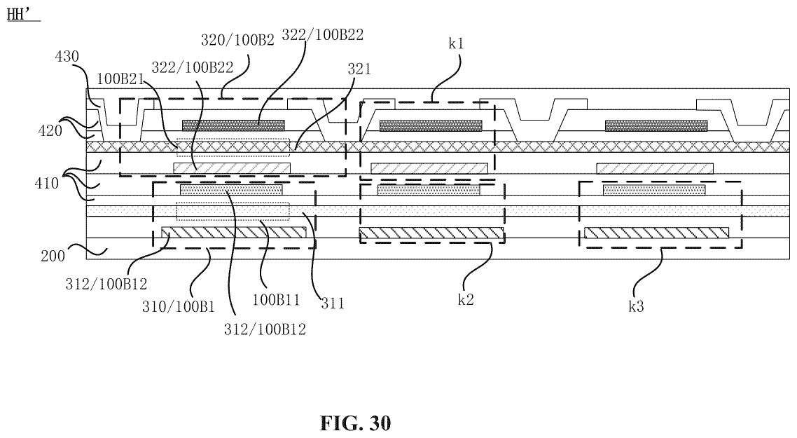

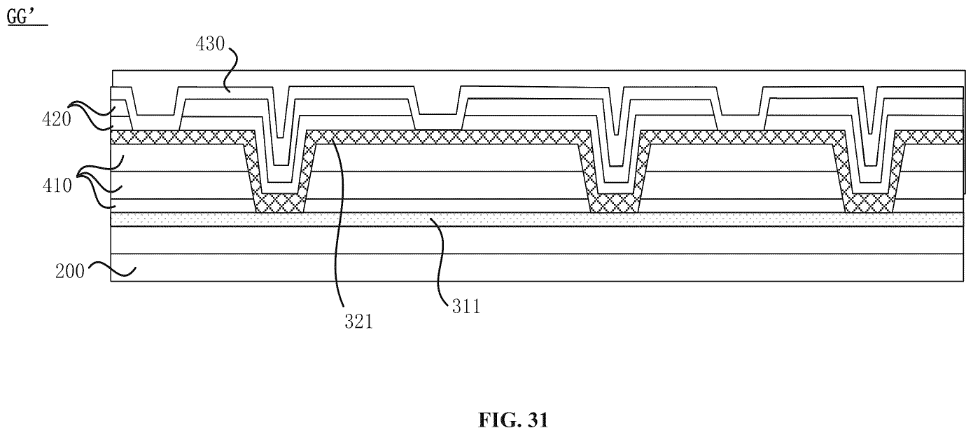

FIG. 29 is a schematic diagram showing a partial structure of a shift register according to an embodiment of the present disclosure, FIG. 30 is a schematic sectional diagram taken along a section line G-G′ of FIG. 29, and FIG. 31 is a schematic sectional diagram taken along a section line H-H′ of FIG. 29. Referring to FIG. 1, FIGS. 29 to FIG. 31, the array substrate 100 further includes the non-display region NA, the non-display region NA includes multiple shift registers 100B which are disposed in cascade, each of the multiple shift registers 100B includes a first transistor 100B1 and a second transistor 100B2, where the first transistor 100B1 is the first-type transistor 310, and the second transistor 100B2 is the second-type transistor 320.

Referring to FIG. 1, the display panel 10 includes a display region AA and a non-display region NA. The display region AA includes a light-emitting element 100C and a pixel driving circuit 100A connected to the light-emitting element 100C, thereby achieving the display function of the display panel 10. The non-display region NA includes the multiple shift registers 100B, and the shift registers 100B are electrically connected to the pixel driving circuit 100A of the display region AA for providing relevant signals for the pixel driving circuit 100A, for example, for providing scan signals for the pixel driving circuit 100A, or providing light-emitting control signals for the pixel driving circuit 100A. The non-display region NA surrounds at least part of the display region AA, specific positions of the display region AA and the non-display region NA are not limited in the embodiments of the present disclosure. The multiple cascaded shift registers 100B disposed in the non-display region NA, may be disposed on one side of the display region AA or on two sides of the display region AA, specific setting positions and the setting number of the shift registers 100B may be adaptively adjusted according to different display panels 10, which is not limited in the embodiments of the present disclosure.

In an embodiment, the shift register 100B of the display panel 10 includes multiple transistors, and the shift register 100B may be “12T3C” or “8T2C’ and the like, and the setting number of transistors and capacitors in the shift register 100B may be adjusted according to the difference in signals output by the shift register 100B, or may be adaptively adjusted according to the specific requirements of the display panel 10, which is not limited in the embodiments of the present disclosure.

In an embodiment, the shift register 100B includes the first transistor 100B1 and the second transistor 100B2, the first transistor 100B1 is the first-type transistor 310, and the second transistor 100B2 is the second-type transistor 320. The transistor in the shift register 100B is the oxide transistor, so that the leakage current condition in the shift register 100B can be effectively avoided, and the operation stability of the shift register 100B can be improved. The transistor in the shift register 100B includes a first-type transistor 310 and a second-type transistor 320. In combination with setting positions of the first-type transistor 310 and the second-type transistor 320, it is ensured that a space occupancy ratio of the shift register 100B in the array substrate 100 is relatively small, which is conducive to reducing the space occupancy ratio of the non-display region NA in the display panel 10, achieving a narrow bezel design, improving the occupation ratio condition of the display region AA, and thus improving the overall display effect of the display panel 10.

With continued reference to FIG. 1, FIGS. 29 to 31, the first transistor 100B1 overlaps with the second transistor 100B2 in the direction perpendicular to the plane on which the substrate 200 is located.

In an embodiment, referring to FIGS. 29 to 31, the first transistor 100B1 is the first-type transistor 310, and the second transistor 100B2 is the second-type transistor 320. The first active layer 311 of the first-type transistor 310 and the second active layer 321 of the second transistor 320 are disposed in different layers, and the active layer of the first transistor 100B1 and the active layer of the second transistor 100B2 are also disposed in different layers.

In an embodiment, referring to FIGS. 29 and 31, an orthographic projection of the first transistor 100B1 on the substrate 200 overlaps with an orthographic projection of the second transistor 100B2 on the substrate 200, that is, the first transistor 100B1 and the second transistor 100B2 are disposed in a laminated manner, in this way, the space occupancy ratio of the transistors in the shift register 100B can be further reduced, the space occupation ratio of the non-display region NA in the display panel 10 can be reduced, the occupation ratio condition of the display region AA can be improved, and thus the overall display effect of the display panel 10 can be improved.

In an embodiment, with continued reference to FIG. 1 and FIGS. 29 to 31, the first transistor 100B1 includes a third gate 100B12 and a third active layer 100B11, and the second transistor 100B2 includes a fourth gate 100B22 and a fourth active layer 100B21. In the direction perpendicular to the plane on which the substrate 22 is located, the third gate 100B12 does not overlap with the fourth gate 100B22, and the third active layer 100B11 overlaps with the fourth active layer 100B21.

Referring to FIGS. 29 to 31, the first transistor 100B1 includes the third gate 100B12 and the third active layer 100B11, in the drawings, an example in which the first transistor 100B1 includes two third gates 100B12 located on two sides of the third active layer 100B11, that is, the first transistor 100B1 is a top-bottom double-gate transistor is used for illustrated. The second transistor 100B2 includes the fourth gate 100B22 and the fourth active layer 100B21, in the drawings, an example in which the second transistor 100B2 includes two fourth gates 100B22 located on two sides of the fourth active layer 100B21, that is, the second transistor 100B2 is a top-bottom double-gate transistor is used for illustrated. It is to be noted that FIG. 29 shows a schematic diagram of part of the film layer of the shift register 100B, and a specific film layer structure of the shift register 100B may be adaptively adjusted according to different display panels 10, which is not limited in the embodiments of the present disclosure.

In an embodiment, referring to FIGS. 29 to 31, the third gate 100B12 does not overlap with the fourth gate 100B22 in the direction perpendicular to the plane on which the substrate 200 is located. In this regard, it is also to be understood that, as shown in FIG. 31, corresponding gates in the first transistor 100B1 and the second transistor 100B2 are located in regions which are independently disposed, and no overlapping part exists, that is, an orthographic projection of the third gate 100B12 on the substrate 200 does not overlap with an orthographic projection of the fourth gate 100B22 on the substrate 200.

Orthographic projections of the third active layer 100B11 and the fourth active layer 100B21, which are disposed in different layers, on the substrate 200 overlap, in other words, the third active layer 100B11 and the fourth active layer 100B21 are located at different film layers; however, the orthographic projection of the third active layer 100B11 on the substrate 200 overlaps with the orthographic projection of the fourth active layer 100B21 on the substrate 200, the third active layer 100B11 and the fourth active layer 100B21 are disposed in a coinciding manner, and an overlapping region of the third active layer 100B11 and the fourth active layer 100B21 has an overlapping region with the third active layer 100B12 and an overlapping region with the fourth gate 100B22. In an embodiment, as shown in FIG. 30, referring to a region k1 and a region k3, in a case where the third active layer 100B11 and the fourth active layer 100B21 are disposed in different layers, the third active layer 100B11 and the fourth active layer 100B21 are disposed in a coinciding manner in the thickness direction of the display panel 10, but the third gate 100B12 and the fourth gate 100B22 are disposed in a staggered manner, which reflects one setting manner of the first transistor 100B1 and the second transistor 100B2 in the shift register 100B; therefore, the overall space occupied by the transistors in the array substrate can be better reduced, thereby improving the overall display effect of the display panel.

With continued reference to FIG. 1 and FIGS. 29 to 31, the first transistor 100B1 includes the third gate 100B12 and the third active layer 100B11, and the second transistor 100B2 includes the fourth gate 100B22 and the fourth active layer 100B21. In the direction perpendicular to the plane on which the substrate 200 is located, the third gate 100B12 overlaps with the fourth gate 100B22, and the third active layer 100B11 overlaps with the fourth active layer 100B21.

In an embodiment, referring to FIGS. 29 to 31, the third gate 100B12 overlaps with the fourth gate 100B22 in the direction perpendicular to the plane on which the substrate 200 is located. In this regard, it is also to be understood that, as shown in FIG. 31, corresponding gates in the first transistor 100B1 and the second transistor 100B2 are disposed in a coinciding manner, that is, the orthographic projection of the third gate 100B12 on the substrate 200 overlaps with the orthographic projection of the fourth gate 100B22 on the substrate 200.

Orthographic projections of the third active layer 100B11 and the fourth active layer 100B21, which are disposed in different layers, on the substrate 200 overlap, in other words, the third active layer 100B11 and the fourth active layer 100B21 are located in different film layers; however, the orthographic projection of the third active layer 100B11 on the substrate 200 overlaps with the orthographic projection of the fourth active layer 100B21 on the substrate 200, the third active layer 100B11 and the fourth active layer 100B21 are disposed in a coinciding manner, and an overlapping region of the third active layer 100B11 and the fourth active layer 100B21 has an overlapping region with the third active layer 100B12 and an overlapping region with the fourth gate 100B22. In an embodiment, as shown in FIG. 30, referring to the region kl and the region k2, in a case where the third active layer 100B11 and the fourth active layer 100B21 are disposed in different layers, the third active layer 100B11 and the fourth active layer 100B21 are disposed in a coinciding manner in the thickness direction of the display panel 10, and the third gate 100B12 and the fourth gate 100B22 are also disposed in a coinciding manner, which reflects another setting manner of the first transistor 100B1 and the second transistor 100B2 in the shift register 100B; therefore, the overall space occupied by the transistors in the array substrate can be better reduced, thereby improving the overall display effect of the display panel.

With continued reference to FIG. 1, the display panel 10 further includes light-emitting elements 100C. The light-emitting elements 100C are electrically connected to the pixel driving circuit 100A. Multiple light-emitting elements among the light-emitting elements 100C form a pixel unit, and the pixel unit has a pixel density greater than or equal to 1000 pixels per inch.

Referring to FIG. 1, the display panel 10C includes multiple light-emitting elements 100C. The multiple light-emitting elements 100C emit light for display under the driving of the pixel driving circuit 100A, thereby achieving the display function of the display panel 10. The light-emitting element 100C may include light-emitting elements 100C of different colors, such as a red light-emitting element, a blue light-emitting element, and a green light-emitting element, to achieve the color display effect of the display panel 10. In an embodiment, the multiple light-emitting elements 100C form a pixel unit, and the pixel unit may be understood as the smallest repeating unit of the multiple light-emitting elements 100C in the display panel 10.

The transistors in the array substrate 100 in the display panel 10 provided in the embodiments of the present disclosure include a first-type transistor 310 and a second-type transistor 320, and both the first-type transistor 310 and the second-type transistor 320 are oxide transistors, to ensure that the pixel driving circuit 100A or the shift register 100B and the like in the display panel 10 have the advantage of the oxide transistor. In an embodiment, the active layers of the first-type transistors 310 and the second-type transistors 320 are disposed in different layers, that is, relative positions of the first-type transistors 310 and the second-type transistors 320 are adjusted by the array substrate 100, so that the occupancy space of the transistors in the array substrate 100 can be saved, and the pixel density of the display panel 10 can be improved, thereby ensuring the better display effect of the display panel 10. In an embodiment, the higher pixel density, i.e., the higher resolution may be used in the AR display device and the VR display device to improve the display effect.

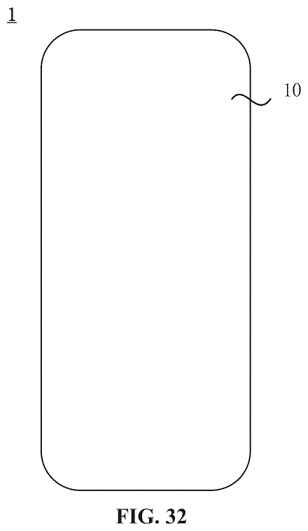

Based on the same inventive conception, the embodiments of the present disclosure further provide a display device. FIG. 32 is a schematic structural diagram of a display device according to an embodiment of the present disclosure. As shown in FIG. 32, the display device 1 includes the display panel 10 described in any of the above embodiments, and thus, the display device 1 provided in the embodiments of the present disclosure possesses the corresponding beneficial effects in the above embodiments, which will not be repeated here. The display device 1 may be an electronic device such as a cell phone, a computer, a smart wearable device (such as, a smart watch, an AR display device, a VR display device), and an in-vehicle display device.

It is to be noted that the above are merely preferred embodiments of the present disclosure and the technical principles applied herein. It should be understood by those skilled in the art that the present disclosure is not limited to the particular embodiments described herein. For those skilled in the art, various apparent modifications, readjustments and substitutions may be made without departing from the scope of protection of the present disclosure. Therefore, although the present disclosure has been described in detail through the above embodiments, the present disclosure is not limited to the above embodiments and may include more other equivalent embodiments without departing from the concept of the present disclosure. The scope of the present disclosure is determined by the scope of the appended claims.

What is claimed is:

1. A display panel, comprising an array substrate, wherein the array substrate comprises:
a substrate; and
a first-type transistor and a second-type transistor, wherein the first-type transistor comprises a first active layer, the second-type transistor comprises a second active layer, and the second active layer is located on a side of the first active layer facing away from the substrate; and
wherein each of the first active layer and the second active layer is an oxide semiconductor active layer.

2. The display panel of claim 1, wherein the first active layer comprises a first channel, the second active layer comprises a second channel, and the first channel does not overlap with the second channel in a direction perpendicular to a plane on which the substrate is located.

3. The display panel of claim 1, wherein the first active layer comprises a first channel, the second active layer comprises a second channel, and the first channel overlaps with the second channel in a direction perpendicular to a plane on which the substrate is located.

4. The display panel of claim 2, wherein the first-type transistor comprises a first gate, and the second-type transistor comprises a second gate; and
in the direction perpendicular to the plane on which the substrate is located, the first gate does not overlap with the second gate and the first active layer does not overlap with the second active layer.

5. The display panel of claim 2, wherein the first-type transistor comprises a first gate, and the second-type transistor comprises a second gate; and
in the direction perpendicular to the plane on which the substrate is located, the first gate does not overlap with the second gate, the first active layer overlaps with the second channel, and the second active layer overlaps with the first channel.

6. The display panel of claim 1, wherein the array substrate further comprises a first insulating layer, a second insulating layer and a source-drain metal layer, the first insulating layer is located between the first active layer and the second active layer, the second insulating layer is located on a side of the second active layer facing away from the first active layer, and the source-drain metal layer is located on a side of the second insulating layer facing away from the second active layer; and
the source-drain metal layer comprises a first source, a first drain, a second source and a second drain, the first source is connected to the second active layer through a first through hole disposed in the second insulating layer, the first drain is connected to the second active layer through a second through hole disposed in the second insulating layer, the second source is connected to the first active layer through a third through hole disposed in the second insulating layer and the first insulating layer, and the second drain is connected to the first active layer through a fourth through hole disposed in the second insulating layer and the first insulating layer.

7. The display panel of claim 4, wherein the first gate comprises a first sub-gate and a second sub-gate, the first sub-gate is located on a side of the first active layer facing the substrate, and the second sub-gate is located on the side of the first active layer facing away from the substrate; and
the second gate comprises a third sub-gate and a fourth sub-gate, the third sub-gate is located on a side of the second active layer facing the substrate, and the fourth sub-gate is located on a side of the second active layer facing away from the substrate.

8. The display panel of claim 7, further comprising an insulating layer located between the first sub-gate and the first active layer, an insulating layer located between the first active layer and the second sub-gate, an insulating layer located between the third sub-gate and the second active layer, and an insulating layer located between the second active layer and the fourth sub-gate, wherein the first sub-gate is connected to the second sub-gate through a fifth through hole of an insulating layer disposed between the first sub-gate and the second sub-gate, and the third sub-gate is connected to the fourth sub-gate through a sixth through hole of an insulating layer disposed between the third sub-gate and the fourth sub-gate.

9. The display panel of claim 1, wherein the array substrate comprises a display region and a pixel driving circuit located in the display region, and the pixel driving circuit comprises a first-type transistor and a second-type transistor.

10. The display panel of claim 9, wherein the pixel driving circuit comprises a drive transistor, a data write transistor, an initialization transistor, a threshold compensation transistor, a first light-emitting control transistor, a second light-emitting control transistor, and a storage capacitor;
a control terminal of the drive transistor is electrically connected to a first node, a first terminal of the drive transistor is electrically connected to a second node, and a second terminal of the drive transistor is electrically connected to a third node;
a control terminal of the first light-emitting control transistor is electrically connected to a first light-emitting control signal line, a first terminal of the first light-emitting control transistor is electrically connected to a first voltage terminal, and a second terminal of the first light-emitting control transistor is electrically connected to the second node;
a control terminal of the threshold compensation transistor is electrically connected to a first scan signal line, a first terminal of the threshold compensation transistor is electrically connected to the second node, and a second terminal of the threshold compensation transistor is electrically connected to the first node;
a first terminal of the storage capacitor is electrically connected to the first node, and a second terminal of the storage capacitor is electrically connected to a fourth node;
a control terminal of the initialization transistor is electrically connected to the first scan signal line, a first terminal of the initialization transistor is electrically connected to the fourth node, and a second terminal of the initialization transistor is electrically connected to an initialization voltage signal line;
a control terminal of the data write transistor is electrically connected to a second scan signal line, a first terminal of the data write transistor is electrically connected to a data line, and a second terminal of the data write transistor is electrically connected to the third node; and
a control terminal of the second light-emitting control transistor is electrically connected to a second light-emitting control signal line, a first terminal of the second light-emitting control transistor is electrically connected to the third node, and a second terminal of the second light-emitting control transistor is electrically connected to the fourth node.

11. The display panel of claim 10, wherein each of the drive transistor, the first light-emitting control transistor and the second light-emitting control transistor is the first-type transistor, and each of the data write transistor, the threshold compensation transistor and the initialization transistor is the second-type transistor.

12. The display panel of claim 11, wherein a channel of the first light-emitting control transistor overlaps with a channel of the threshold compensation transistor in a direction perpendicular to a plane on which the substrate is located;
the array substrate further comprises a first insulating layer, a second insulating layer and a source-drain metal layer, the first insulating layer is located between the first active layer and the second active layer, the second insulating layer is located on a side of the second active layer facing away from the first active layer, and the source-drain metal layer is located on a side of the second insulating layer facing away from the second active layer; and
the source-drain metal layer comprises a source of the first light-emitting control transistor and a source wire of the threshold compensation transistor, the source of the first light-emitting control transistor is connected to an active layer of a source region of the first light-emitting control transistor through a seventh through hole disposed in the second insulating layer and the first insulating layer, an active layer of a drain region of the first light-emitting control transistor is connected to an active layer of a drain region of the threshold compensation transistor through an eighth through hole disposed in the first insulating layer, a first terminal of the source wire of the threshold compensation transistor is connected to the second active layer through a ninth through hole disposed in the second insulating layer, and a second terminal of the source wire of the threshold compensation transistor is connected to a gate of the drive transistor through a tenth through hole disposed in the second insulating layer and the first insulating layer.

13. The display panel of claim 11, wherein in a plane on which the substrate is located, the first light-emitting control signal line and the first scan signal line extend in a same direction and at least partially overlap, and a channel of the first light-emitting control transistor overlaps with a channel of the threshold compensation transistor in a direction perpendicular to the substrate.

14. The display panel of claim 11, wherein in a plane on which the substrate is located, the second light-emitting control signal line and the second scan signal line extend in a same direction and at least partially overlap.

15. The display panel of claim 9, wherein the pixel driving circuit comprises a first pixel driving circuit and a second pixel driving circuit, and the first pixel circuit and the second pixel circuit are disposed in axial symmetry.

16. The display panel of claim 1, wherein the array substrate further comprises a non-display region, the non-display region comprises a plurality of shift registers which are disposed in cascade, each of the plurality of shift registers comprises a first transistor and a second transistor, the first transistor is the first-type transistor, and the second transistor is the second-type transistor.

17. The display panel of claim 16, wherein the first transistor overlaps with the second transistor in a direction perpendicular to a plane on which the substrate is located.

18. The display panel of claim 17, wherein the first transistor comprises a third gate and a third active layer, and the second transistor comprises a fourth gate and a fourth active layer; and
in the direction perpendicular to the plane on which the substrate is located, the third gate does not overlap with the fourth gate, and the third active layer overlap with the fourth active layer.

19. The display panel of claim 17, wherein the first transistor comprises a third gate and a third active layer, and the second transistor comprises a fourth gate and a fourth active layer; and
in the direction perpendicular to the plane on which the substrate is located, the third gate overlaps with the fourth gate, and the third active layer overlaps with the fourth active layer.

20. The display panel of claim 9, further comprising light-emitting elements, wherein the light-emitting elements are electrically connected to the pixel driving circuit; and
a plurality of light-emitting elements among the light-emitting elements form a pixel unit, and the pixel unit has a pixel density greater than or equal to 1000 pixels per inch.

21. A display device, comprising a display panel, wherein the display panel comprises an array substrate, wherein the array substrate comprises:
a substrate; and
a first-type transistor and a second-type transistor, wherein the first-type transistor comprises a first active layer, the second-type transistor comprises a second active layer, and the second active layer is located on a side of the first active layer facing away from the substrate; and
wherein each of the first active layer and the second active layer is an oxide semiconductor active layer.
